(19) United States
(12) Patent Application Publication
(10) Pub. No.: US 2022/0374428 A1
(43) Pub. Date: Nov. 24, 2022

(54) SIMULATION QUERY ENGINE IN AUTONOMOUS MACHINE APPLICATIONS

(71) Applicant: NVIDIA Corporation, Santa Clara, CA (US)

(72) Inventors: Ahmed Nassar, San Jose, CA (US); David Robert Auld, Saratoga, CA (US); Justyna Zander, Cupertino, CA (US)

(21) Appl. No.: 17/328,505

(22) Filed: May 24, 2021

(51) Int. Cl. G06F 16/2452; G06F 16/28

(52) U.S. Cl. CPC G06F 16/24526; G06F 16/284; G06F 30/20

(57) ABSTRACT

In various examples, searching of data—including real-world data, simulation data, system under test (SUT) data, and/or map data—may be executed using a query engine configured to compile detailed binary code from high-level declarative queries for searching the data to identify scenarios or engineering artifacts of interest. A user may identify a behavior or scenario of interest, define the behavior or scenario in a descriptive and/or declarative manner—including implicit indications of temporal or spatial relationships—and the query engine may then compile an explicit procedural description that may be used to search the data for one or more instances and/or variations of the defined scenario or computational representation of an engineering artifact under investigation. Once the scenarios are identified, behaviors of the machine may be observed, criteria with respect to the machine performance may be evaluated, and/or test coverage with respect to the scenario type may be collected.

### CROSS-REFERENCE TO RELATED APPLICATIONS

This application is related to U.S. Non-Provisional application Ser. No. 16/824,202, filed on Mar. 19, 2020, and U.S. Non-Provisional application Ser. No. 16/366,875, filed on Mar. 27, 2019, each of which is hereby incorporated by reference in its entirety.

### BACKGROUND

During development of an autonomous or semi-autonomous machine (e.g., a vehicle, robot, machinery, etc.)—and due to the safety-critical nature of such systems—being able to accurately and reliably query, analyze, measure, quantify, verify, validate and/or test the functionality and performance of the machine in a large number of situations and environments is critical to ensuring the machine performs safely. In particular, analysis and testing may be used to verify that the machine can safely operate within a real-world environment where millions of different scenarios may be encountered. One way to test autonomous machines—including hardware and/or underlying software of the machine—is to use simulated environments and/or real-world environments to model various scenarios the machine may encounter when deployed for use. For instance, one or more abstract representations and/or computational models (e.g., machine learning models, deep neural networks (DNNs), computer vision algorithms, etc.) corresponding to an autonomous or semi-autonomous software stack—such as for object detection, lane and road boundary detection, safety analysis, drivable free-space analysis, control generation during vehicle maneuvers, etc. —may be tested against data gathered from within a virtual and/or real-world environment.

For example, in a conventional system, in an attempt to analyze, design, test, verify, validate, and/or improve an autonomous machine, a scenario of interest may be hard-coded—or created manually—within the virtual and/or computational environment, and the performance of the machine in the generated or created scenario may be tested. In such an example, an engineer can attempt to program a scenario (e.g., using a programming language such as Python, MATLAB, Simulink specification, etc.) within the virtual and/or computational environment by manually defining the particular scene, traffic, agents, and/or the actors therein, as well as the exact spatial and temporal relationships between them. However, due to the complexity of scenarios for designing, analyzing, verifying and validating autonomous vehicles, creating scenarios in this manner often results in mistakes and/or does not comprehend the entire domain, search space, and/or meaningful coverage of all possible test objectives and/or safety-critical system requirements (e.g., in the code, the scenario, etc.). In addition, because each scenario must be manually defined, and any variations of the scenario must also be manually defined, the ability to test a full range of scenarios at a scale that is suitable for verifying and validating an autonomous system to achieve a desired level of safety is a challenging task. As such, these conventional systems do not provide an intuitive method for easily defining millions of corner scenarios of interest—and variations thereof.

As another example, a user with intimate knowledge of various real-world drives of the autonomous machine may manually search through data from the drives to identify the scenario of interest, and may analyze data generated by the machine during the drives to determine performance of the autonomous machine in the scenario. However, searching through data from drives which may span thousands of miles through various environments may prove challenging and time consuming, and may not result in identifying or encountering each of the desired scenarios required to adequately test the performance of the autonomous machine. As a result, the user is required to either request that a test vehicle be deployed to satisfy a particular scenario, or require that the scenario be scripted in the virtual environment to virtually test the machine performance.

### SUMMARY

Embodiments of the present disclosure relate to a query engine for designing, analyzing, optimizing, verifying, and/or validating simulations and simulated data in autonomous machine applications. Systems and methods are disclosed that allow for searching of test data—including real-world data, simulation data, system under test (SUT) data, and/or map data—using a query engine configured to compile detailed binary code from high-level declarative queries for searching the test data to identify the engineering artifacts, situations, and/or scenarios of interest. As a result, and in contrast to conventional systems, a user needs only a high-level understanding of the particular domain ontology or world model associated with the query to search complex and extensive test data for finding particular items and/or scenarios of interest. As such, a user may identify a behavior or scenario of interest, define the behavior or scenario in a descriptive and/or declarative manner—including implicit indications of temporal or spatial relationships (e.g., using query operators such as “parallel,” “sequential,” etc., or domain ontology specific language such as “following,” “in same lane,” etc.)—and the query engine may then compile the implicit information in the declarative description into an explicit procedural description or code that may be used to search the test data for one or more instances and/or variations of the defined scenario. Once the scenarios are identified, observers, evaluators, and/or coverage collectors may be implemented—as defined in the declarative query—that observe behaviors of the machine, measure, optimize, quantify, and/or evaluate certain criteria with respect to the machine performance, and/or determine test coverage with respect to the scenario type, respectively.

As a result, the high-level query may include a minimal level of detail and, where details are left out, the query engine may search for concrete values and/or parameters corresponding to defined criteria and/or requirements within the simulation-runs data in order to identify the one or more scenarios from within the test data that satisfy the high-level requirements (or to identify that such scenarios do not exist via a coverage collector, thus indicating additional testing may be required). In some embodiments, the query engine may employ various optimizations to decrease compute and runtime of queries. For example, the query engine may rearrange the order of the query to limit the search space, or may add sub-expressions identified from the query as primary expressions for limiting the search space (e.g., if expression includes vehicle x following vehicle y, the sub-expression that both x and y are in the same lane may be added to the search query to limit the search space to only vehicles in a same lane). In addition, various caching strategies may be used to save compute over iterative searches. In such an example, instead of generating relational databases that define entire test data sets—which would be inefficient and require expensive compute resources—so-called “lazy” evaluation may be used to generate a database representation during a search such that the databases include data relevant to the particular search.

Ultimately, the query engine may identify different variations of a defined scenario, determine performance of the autonomous machine within the defined and/or discovered scenarios, and feed the results back to the system for generating updated or additional scenarios that more accurately comply with the scenarios desired, and/or update features or modules of the autonomous system (e.g., for self-monitoring or self-healing purposes for the system under test to advance its own functionality).

### BRIEF DESCRIPTION OF THE DRAWINGS

The present systems and methods for a query engine for testing in autonomous machine applications are described in detail below with reference to the attached drawing figures, wherein:

FIG. 1 is a block diagram illustrating a query system, in accordance with some embodiments of the present disclosure;

FIG. 2A is an illustration of an example declarative query for processing by a query system, in accordance with some embodiments of the present disclosure;

FIG. 2B is a visualization of an example scenario as described in the example declarative query of FIG. 2A, in accordance with some embodiments of the present disclosure;

FIG. 2C is an illustration of different time windows corresponding to the example declarative query of FIG. 2A, in accordance with some embodiments of the present disclosure;

FIG. 3A is an illustration of an example declarative query for processing by a query system, in accordance with some embodiments of the present disclosure;

FIG. 3B is a visualization of an example scenario as described in the example declarative query of FIG. 3B, in accordance with some embodiments of the present disclosure;

FIG. 4A is an illustration of an example declarative query for processing by a query system, in accordance with some embodiments of the present disclosure;

FIG. 4B is a visualization of an example scenario as described in the example declarative query of FIG. 4B, in accordance with some embodiments of the present disclosure;

FIG. 5 is a visualization of an example scenario searchable by a query system, in accordance with some embodiments of the present disclosure;

FIG. 6 is a flow diagram of a method for executing a query using a query engine, in accordance with some embodiments of the present disclosure;

FIG. 7A is an illustration of an example autonomous vehicle, in accordance with some embodiments of the present disclosure;

FIG. 7B is an example of camera locations and fields of view for the example autonomous vehicle of FIG. 7A, in accordance with some embodiments of the present disclosure;

FIG. 7C is a block diagram of an example system architecture for the example autonomous vehicle of FIG. 7A, in accordance with some embodiments of the present disclosure;

FIG. 7D is a system diagram for communication between cloud-based server(s) and the example autonomous vehicle of FIG. 7A, in accordance with some embodiments of the present disclosure;

FIG. 8 is a block diagram of an example computing device suitable for use in implementing some embodiments of the present disclosure; and

FIG. 9 is a block diagram of an example data center suitable for use in implementing some embodiments of the present disclosure.

### DETAILED DESCRIPTION

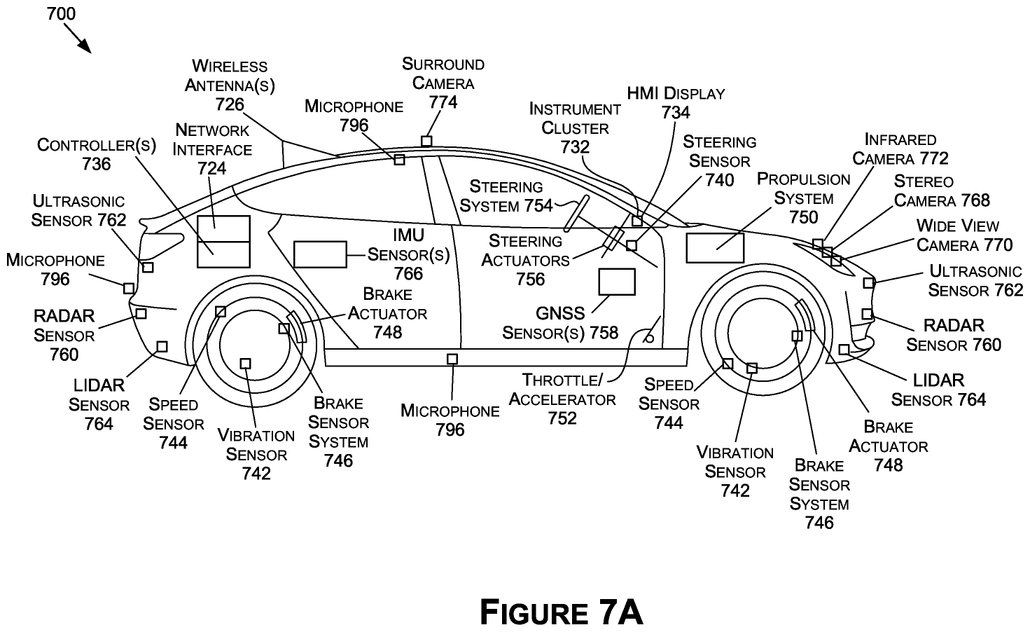

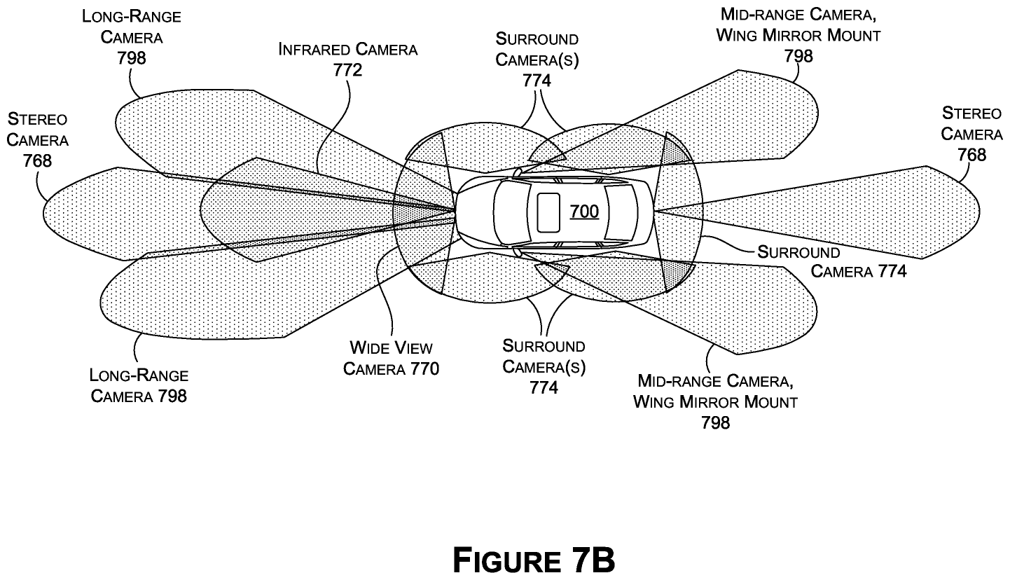

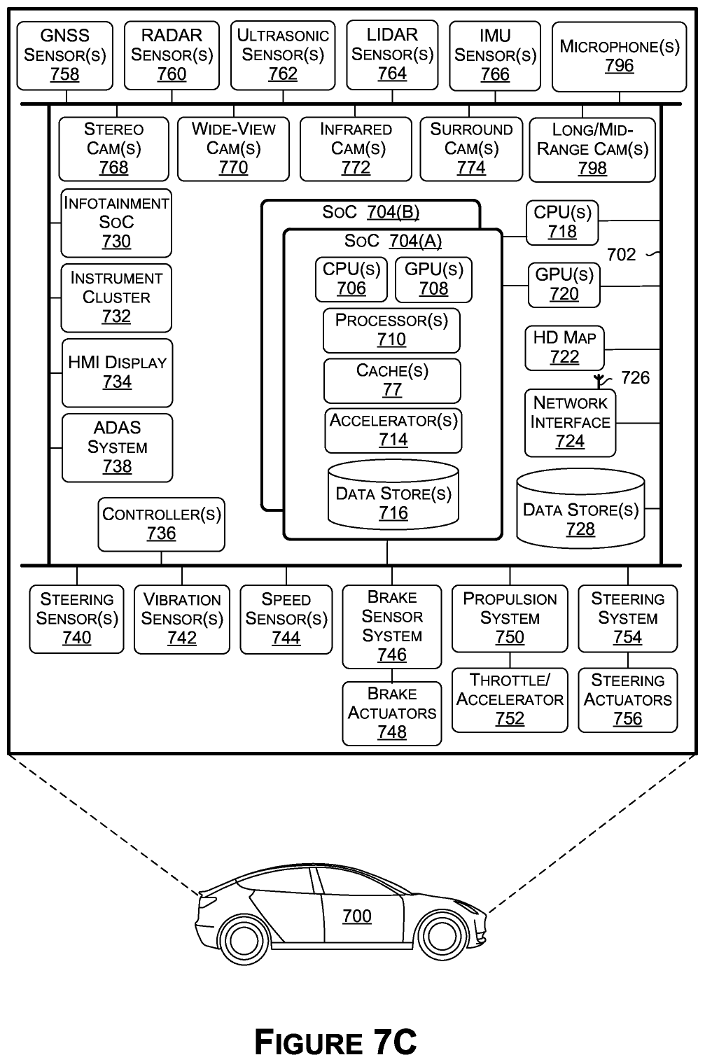

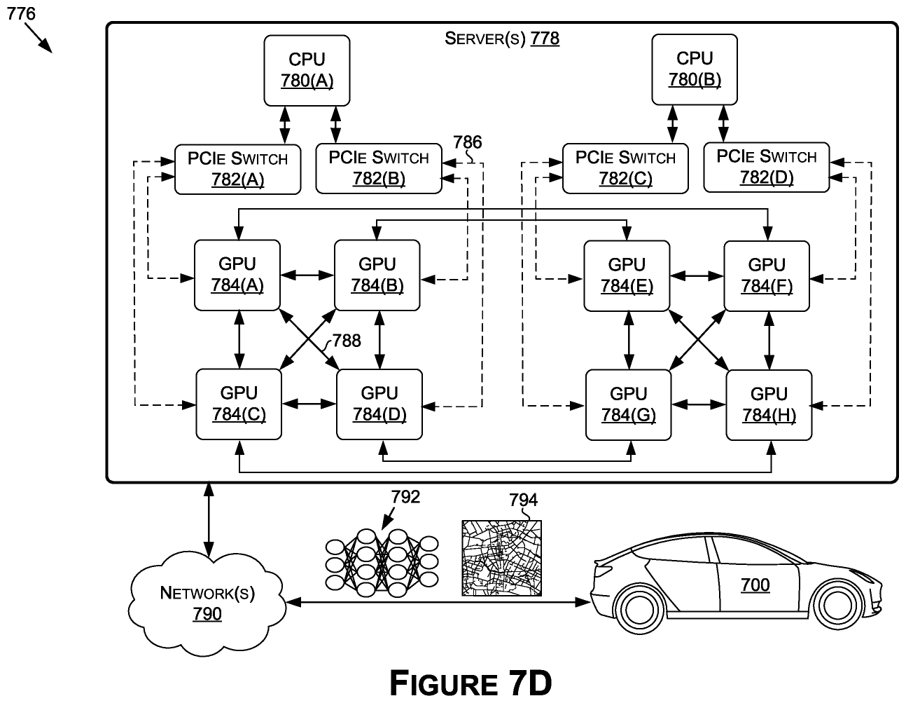

Systems and methods are disclosed related to a query engine for design, analysis, measurement, verification, validation and/or testing in autonomous machine applications. Although the present disclosure may be described with respect to an example autonomous vehicle 700 (alternatively referred to herein as “vehicle 700” or “ego-vehicle 700,” an example of which is described with respect to FIGS. 7A-7D), this is not intended to be limiting. For example, the systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. In addition, although the present disclosure may be described with respect to a query engine for testing autonomous vehicle systems, this is not intended to be limiting, and the systems and methods described herein may be used in robotics, security and surveillance applications, autonomous or semi-autonomous machine applications, and/or any other technology spaces where design, analysis, and/or testing of systems in a variety of scenarios is desired.

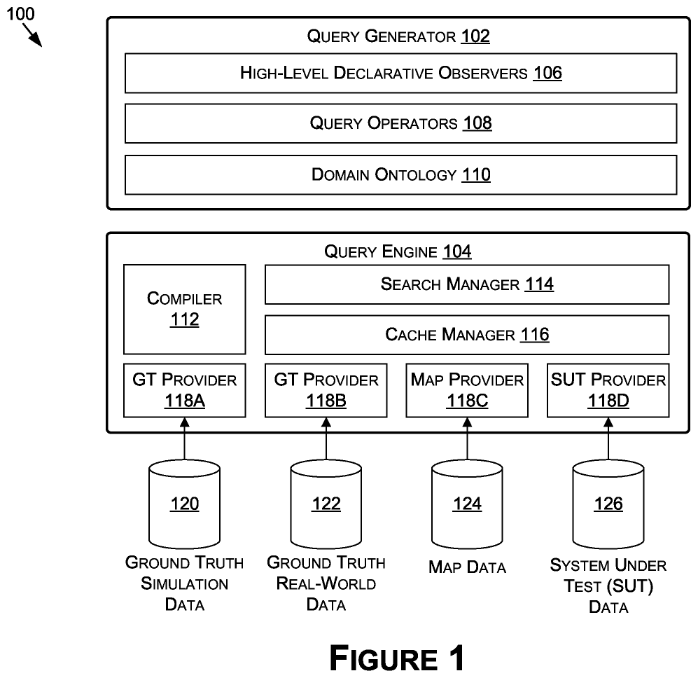

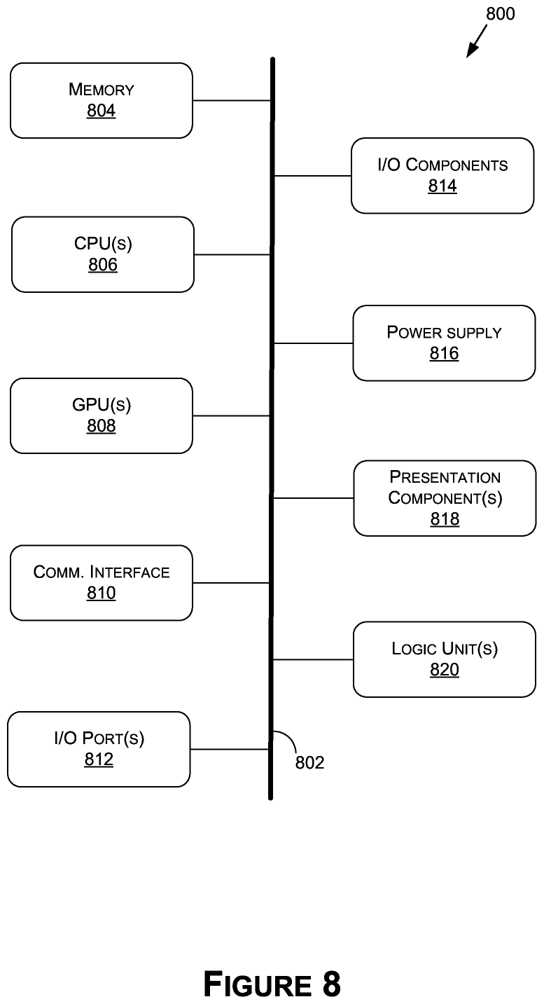

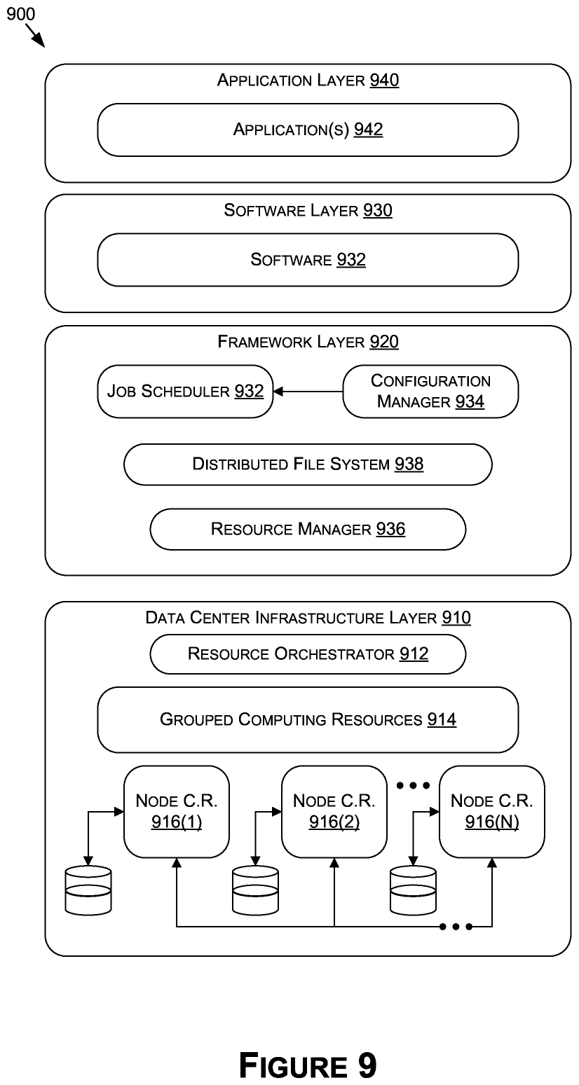

With reference to FIG. 1, FIG. 1 is an example query engine system, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. In some embodiments, the components, features, and/or functionality described with respect to the system 100 may similar to those described with respect to vehicle 700 of FIGS. 7A-7D, example computing device 800 of FIG. 8, and/or example data center 900 of FIG. 9.

The query engine system 100 (alternatively referred to herein as “system 100”) may include a query generator 102, a query engine 104, and various data sources—e.g., ground truth simulation data 120, ground truth real-world data 122, map data 124, and/or system under test (SUT) data 126. The query generator 102 may be, in embodiments, a user-facing portion of the system 100 such that a user may use the query generator 102 to generate queries—e.g., high level declarative queries—that may be used by the query engine 104 to generate low level procedural queries for searching the data sources. For example, an initial query from the query generator 102 may include one or more scenarios and/or one or more observers, evaluators, and/or coverage collectors that are defined using high-level declarative observers 106 (alternatively referred to herein as “observers 106”), query operators 108, and/or a domain ontology 110 (alternatively referred to herein as “world model 110”). In some embodiments, the query language may include high level scenario description language (HSDL) and/or OpenSCENARIO language. The query engine 104 may use the initial query to bind symbolic variables (e.g., vehicle X, pedestrian Y, lane Z) to concrete values, find phase and/or interval boundaries, evaluate predicates and functions, and/or keep track of parallel, sequential, and/or alternative phases. As a result, a user with a high level understanding of a particular domain may generate queries without intimate knowledge of the data available in the various data sources. For example, without defining a unique search algorithm for each scenario, a user may generate a query that describes what the user wants to see in the data, without requiring knowledge of—e.g., with respect to autonomous vehicle scene—the scene, the vehicle, how the vehicle works, etc. As such, the query generator 102 allows abstraction away from intimate knowledge of a scene or the inner workings of the vehicle, and allow for high level descriptions that can be filled in by the query engine by finding scenes or scenarios that fall within the implied requirements of the query. The query engine 104 may generate a more explicit query—using one or more optimizations—to search the data sources to identify scenarios that match the scenario implicitly defined by the query from the query generator 102. Once a scenario(s) is identified, various observations and/or evaluations of performance of the autonomous machine—e.g., the vehicle 700—through the scenario(s) may be executed to test the autonomous machine. In addition, in some embodiments, coverage collectors may be used to keep track of whether certain scenarios to be tested were present or identified in the data sources. In some embodiments, the observers, evaluators, and/or coverage collectors may be similar to those described in U.S. Non-Provisional application Ser. No. 16/366,875, filed on Mar. 27, 2019, titled “Training, Testing, and Verifying Autonomous Machines Using Simulated Environments.”

The observers 106 may describe relevant actors, relations, events, actions, and/or scenarios—e.g., without defining the domain specific values (e.g., for the operation “select ‘X’ from vehicles”, “select ‘X’ from” may correspond to the observers 106 while “vehicles” may correspond to the domain ontology 110). The observers 106 may correspond to an expression that describes the scenario in a declarative manner such that one or more values are declared at a high level without specifying how to search for the values in the data sources. The query operators 108 may include phases, combinators, and/or variables. As an example, the query operators 108 may include operators such as select, where, parallel, sequential, alternative, mutually exclusive, always, eventually, and/or other domain independent operators. As such, whether the domain is autonomous vehicles, robots, or another domain, the query operators may be used similarly by the query engine 104 to generate procedural queries. The domain ontology 110 may include the vocabulary for a specific domain or world model. For example, the domain ontology 110 may include object types and relations corresponding to a particular domain. Where the domain is autonomous vehicles, for example, the domain ontology 110 may include object types such as vehicles, pedestrians, lanes, signs, traffic laws, etc., and the relations may include spatial proximity, correspondence between traffic lights and lanes, priorities and rights of way, etc.

By separating the observers 106 and/or the query operators 108 from the domain ontology 110, unique domains may be used by the system 100 without requiring new high level declarative scenario descriptions. For example, operations such as “select” or “parallel” may apply to any domain, so these operations may be used for any domain type. In an autonomous vehicle domain, the select operation may correspond to selecting domain specific values such as vehicles or pedestrians, and the parallel operation may include an ego-vehicle following a first vehicle in parallel with a second vehicle being stalled in a lane of the ego-vehicle. In a robotics domain, the select operation may correspond to selecting domain specific values such as objects in a kitchen, and the parallel operation may include a robot sliding a first object in parallel with picking up a second object. As such, a user who understands the query operators and the scenario description language (e.g., the observer 106) may generate queries with a high level understanding of a particular domain, and without particular knowledge of how to search for particular scenarios in the data sources.

The queries generated by the query generator 102 may be expressed, in embodiments, using first order logic to define, e.g., time variables, object variables, quantifiers (for all, for some, etc.), predicates, and/or functions. In some embodiments, first order interval logic may be used which may similar to the first order logic, but may include implicit time indications as formulas may be defined over intervals. As such, the queries generated by the query generator 102 may include explicit values and/or implicit indications of relationships in time and/or space. For example, phrases or operations such as “following,” “sequential,” “eventually,” etc. may include implicit indications of time and/or space. In such an example, “following” may include an implicit indication that one object (e.g., a first vehicle) is following—e.g., located behind in a same lane of travel—as another object (e.g., a second vehicle). Similarly, “eventually” may include an implicit indication that at some point in time a state, action, actor, event, etc. takes place, which means there is a first time frame prior to the point in time, a second time frame corresponding to the state, action, actor, event, etc., and/or a third time frame after the point in time or after the state, action, actor, event, etc. takes place. As another example, “sequential” may include an implicit indication that two or more things are taking place over an (at least partially) overlapping period of time. As a result, these phrases or operators may be used by the query engine 104 to generate more low level procedural queries that include explicit values, such as a time, t1, a time, t2, and/or a time, t3, corresponding to the “eventually” example described above, and then to search the data sources to identify a scenario that satisfies the requirements within the time windows. The explicit values in the initial query from the query generator 102 may correspond to objects, actions, events, etc., such as vehicles, pedestrians, signs, changing lanes, etc.

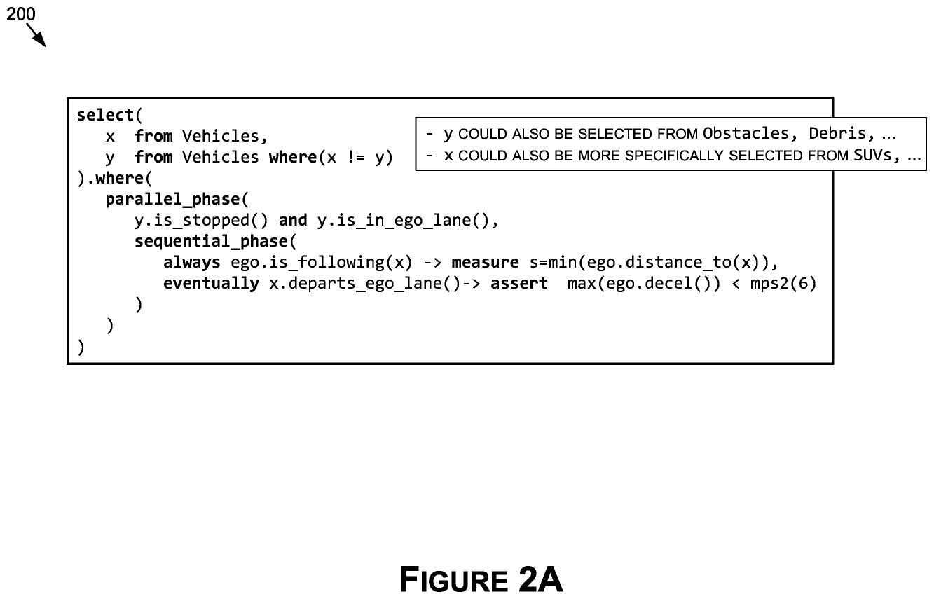

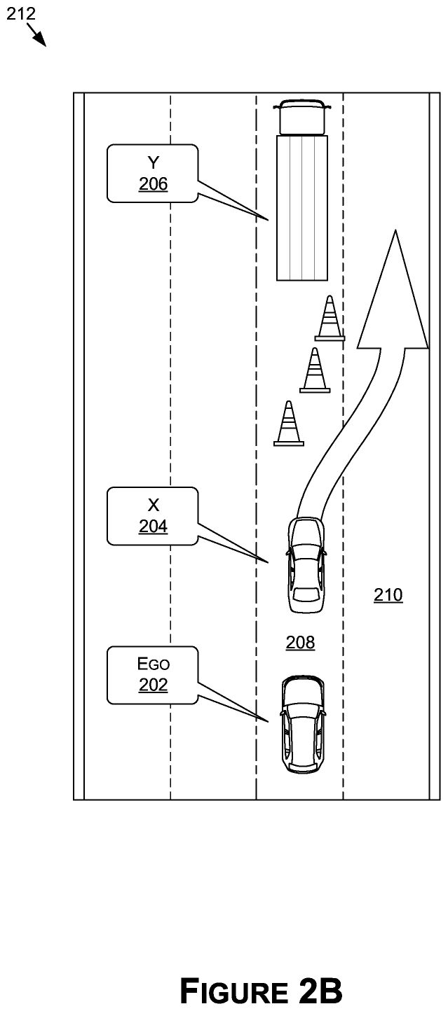

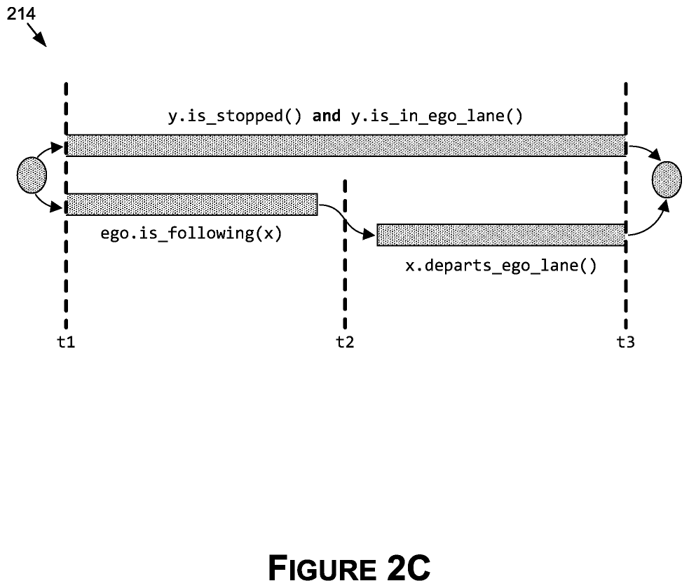

As an example of a query 200 generated using the query generator 102, and with respect to FIGS. 2A-2C, a scenario may be defined to include two vehicles, x 204 and y 206, where x 204 is not y 206, y 206 is stopped in an ego-lane 208 (e.g., a lane of the ego-vehicle 202), ego-vehicle 202 is following x 204, and eventually x 204 departs from the ego-lane 208 such that stopped vehicle y 206, which was previously occluded by vehicle x 204, is now visible to the ego-vehicle 202. Once vehicle x 204 departs the ego-lane 208 to an adjacent lane 210, an observer may measure a minimum distance of the ego-vehicle 202 to vehicle x 204 and an evaluator may assert (e.g., evaluate whether the criteria is met over the time period) that a max deceleration of the ego-vehicle 202 is always less than a desired meter per second per second value. In the query 200, “select,” “where,” “parallel_phase,” “sequential_phase,” “always,” and “eventually,” may correspond to the observers 106 and/or the query operators 108, and may be domain independent. For example, where the query 200 corresponds to an autonomous vehicle domain, these domain-independent words may not indicate or be related to the specific domain ontology 110. “Vehicles,” “is stopped,” “is_in_ego_lane,” “is_following,” and “departs_ego_lane,” may correspond to the domain ontology 110 and may include specific actors (e.g., vehicles), states (e.g., stopped, following, etc.), actions (e.g., departs), locations (e.g., in ego-lane), etc. that are unique to the autonomous vehicle domain. “Measure” and “assert” may correspond to domain-independent directives (e.g., observers, evaluators, and/or coverage collectors) for measuring performance of the autonomous vehicle during the identified scenarios (e.g., once the scenarios are identified from the data sources by the query engine 104) and/or for measuring whether the scenarios were presents or how many times the scenarios were present in the data sources. Although x and y are both selected from a “vehicles” class, this is not intended to be limiting, and each or both of x and y could alternatively be selected from an obstacles class, a debris class, a more granular class of vehicles (e.g., sport utility vehicles (SUVs), cars, trucks, etc.), etc.

The query 200 may be designed to find scenarios where (as illustrated in visualization 212) an ego-vehicle 202 has to behave a certain way when encountering a stalled or stopped vehicle y 206 or other object in the roadway that becomes visible only after an occluding object (e.g., a vehicle x 204) departs the lane 208 of the ego-vehicle 202 (e.g., abruptly). Once the scenario is identified, the performance of the ego-vehicle during the scenario—e.g., maintaining a safe distance from vehicle x and decelerating at a rate below a max value—may be evaluated to determine whether there are an issues with the vehicle and, if present, the root cause of those issues. For example, the scenarios in the data sources may indicate that the follow distance of the ego-vehicle was too close to vehicle x at some point in time, and the SUT data 126, for example, corresponding to the same point in time may be evaluated to determine if there was an error in a perception system of the ego-vehicle, an actuation system of the ego-vehicle, an electronic control unit (ECU) of the ego-vehicle, etc. Once an issue is identified, updates or modifications may be made to increase the performance and thus the safety of the system.

The query 200 does not include any explicit temporal or spatial relationships between the actors—e.g., the ego-vehicle 202, the vehicle x 204, and the vehicle y 206—but rather includes implicit temporal and spatial relationships. These implicit relationships may be used by a compiler 112 of the query engine 204 to define explicit temporal and/or spatial relationships for searching the data sources for the specific scenario. For example, and with respect to visualization 214 of FIG. 2C, between a first time, t1, and a second time, t2, vehicle y 206 is stopped in the ego-lane 208 and the ego-vehicle 202 is following the vehicle x 204. At time, t2, vehicle x 204 begins to depart the ego-lane 208 and toward the lane 210 until the vehicle x 204 has left the ego-lane 208 and the ego-vehicle 202 is not confronted with the vehicle y 206 stopped in the ego-lane 210 at time, t3. As such, a user does not need to define the time intervals, or the times, or the spatial relationships explicitly to search the data sources, but only needs to describe what the user wants to see in the data sources at a high level, and the query engine 104 determines the existence of explicit spatial and/or temporal relationships from the high level declarative query. As such, the query engine 104 may identify a time, t1, in the data sources where vehicle y 206 is stopped and in the ego-lane 208, and the ego-vehicle 202 is following vehicle x 204. The query engine 104 may then identify another time, t2, after t1 (while ensuring the other values held true during t1 to t2) in the data sources where vehicle x 204 departs the ego-lane 208 toward the lane 210 and the vehicle y 206 is now a closest vehicle or object to the ego-vehicle 202 in the ego-lane 208. As described in more detail herein, the query engine 204 may use one or more optimizations—e.g., query optimizations, search optimizations, cache optimizations, etc. —to generate the procedural queries and execute the procedural queries more efficiently.

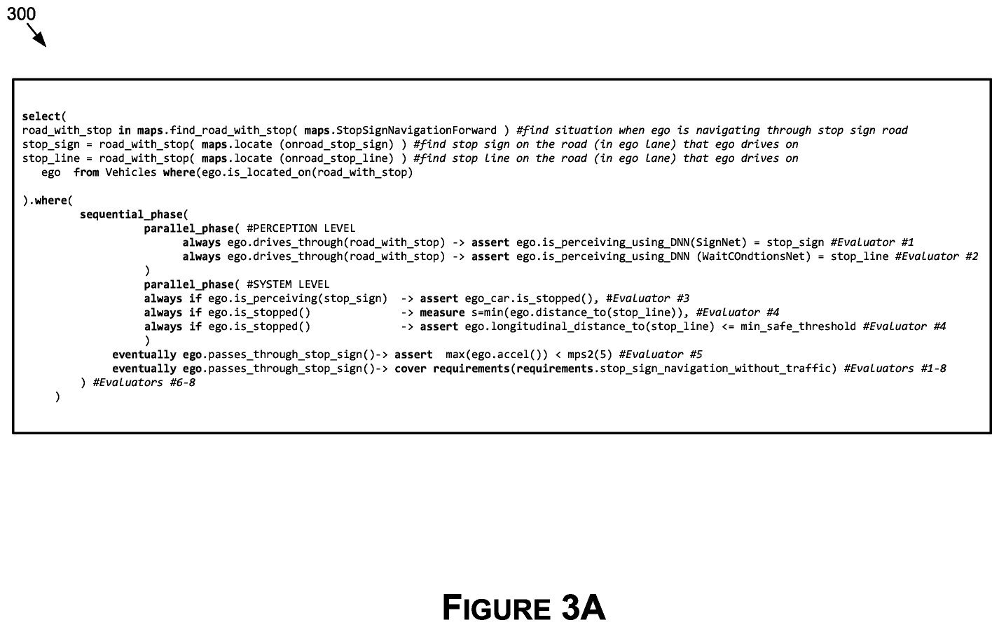

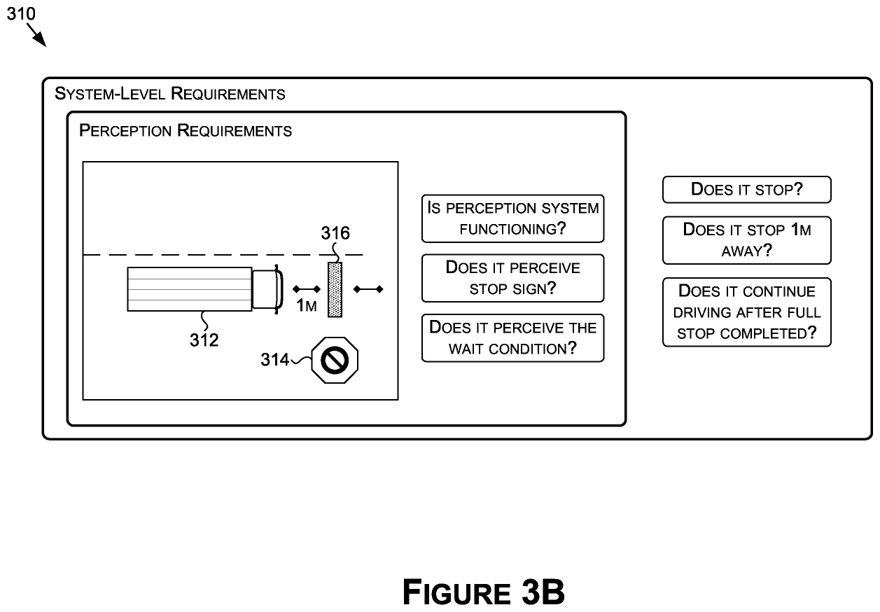

As another example of a query 300, and with respect to FIGS. 3A-3B, the query 300 may be generated to find scenarios represented in the data sources that include a stop sign 314 in a lane of an ego-vehicle 312. For example, visualization 310 of FIG. 3B includes various system level and perception level requirements that may be tested or validated for the vehicle 700, and the query generator 102 may be used to generate queries that will be used by the query engine 104 to identify scenarios from the data sources that allow for testing and validation (e.g., querying) of the various requirements. The requirements may include—at a perception level—ensuring that the perception system is running, that the stop sign 314 was perceived, and that the stop sign 314 along with stop lines 316 are perceived by the ego-vehicle 312 as a wait condition (e.g., necessitating a stop by the ego-vehicle 312). At a system level, the requirements may include that the ego-vehicle 312 stops 1 meter or more before the stop line 316, and continues driving after coming to a complete stop. The query 300 may include a high level description of the scenario and various observers, evaluators, and/or coverage checkers (e.g., indicated by assert, measure, and cover in query 300) that may be executed for the various scenarios identified by the query engine 104. The high level description, similar to that of the query 200 of FIG. 2A, may include domain agnostic operators, phases, etc., such as “select,” “where,” “sequential_phase,” “always,” “eventually,” etc., and domain specific (e.g., in an autonomous vehicle domain) operators, actions, actors, etc., such as “ego. drives_through (road_with_stop),” “ego.is_perceiving (stop_sign),” etc.

In the query 300, the system level requirements may correspond, at least in part, to an ECU of the ego-vehicle 312. For example, the ECU may report information such as what objects are perceived in the environment, what lanes the objects are located in, objectives for objects (e.g., bounding shapes), speed, distance, and location of objects, etc. In addition, the system level requirements may include fault modes of sensors of the ego-vehicle 312. As such, anything that affects the driving behavior of the vehicle 700 may be tested or evaluated, including perception of an interior and/or exterior to the vehicle, sensor function and performance, ECU hardware and software performance, brakes and steering, etc. In some embodiments, the testing of the vehicle 700 may include hardware-in-the-loop (HIL) testing where the actual hardware of the vehicle 700 is tested on simulated data, software-in-the-loop (SIL) testing where the actual software of the vehicle 700 is tested on simulated data, perception-only testing where only the perception systems of the vehicle 700 are tested, real-world testing of the vehicle, or a combination thereof. Non-limiting examples of HIL and SIL testing in simulation environments are described in U.S. Non-Provisional application Ser. No. 16/366,875, filed on Mar. 27, 2019, which is hereby incorporated by reference in its entirety.

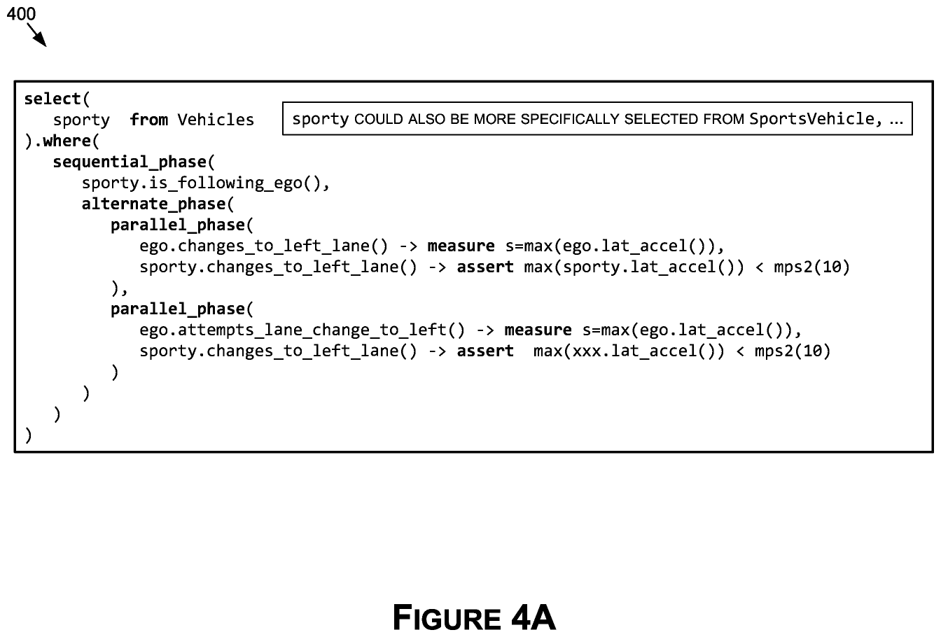

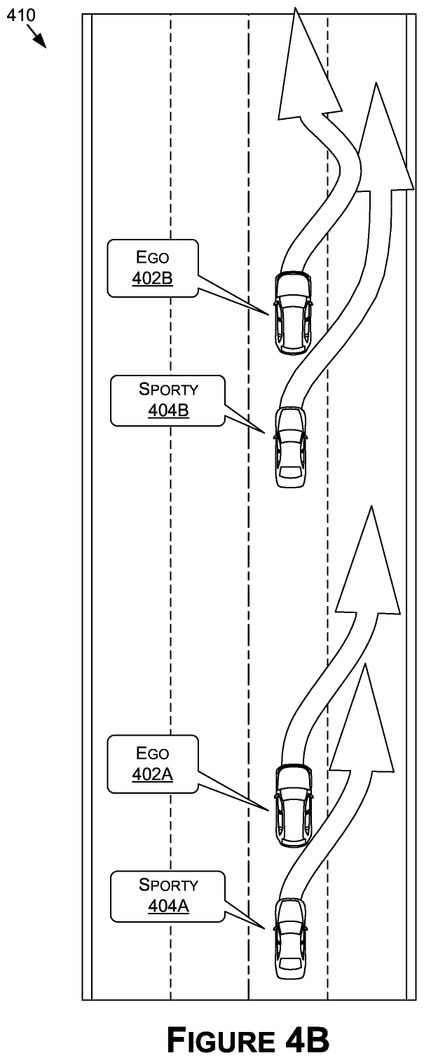

As another example of a query 400, and with respect to FIGS. 4A-4B, the query 400 may be generated to find scenarios represented in the data sources—e.g., as represented by visualization 410—that include an ego-vehicle 402 (e.g., ego-vehicle 402A and 402B) and a sport utility vehicle 404 (e.g., sport utility vehicle 404A and 404B), where the sport utility vehicle 404 is behind the ego-vehicle 402 in the ego-lane, and the sport utility vehicle 404 is attempting to overtake the ego-vehicle 402. The query 400 includes another type of query operator 108, “alternate phase,” where various alternatives may be used to satisfy the scenario of the query 400. For example, in the visualization 410, one alternative is that the sport utility vehicle 404A tries to overtake the ego-vehicle 402A by changing lanes to the right, and at the same time the ego-vehicle 402A tries to change lanes to the right. Another alternative, as represented in the visualization 410, is that the sport utility vehicle 404B tries to overtake the ego-vehicle 402B by changing lanes to the right, the ego-vehicle 402B also tries to change lanes to the right, but then aborts the lane change and enters back into the ego-lane. In addition to these two alternatives, other alternatives may exist in the data sources that satisfy the scenario defined by the query 400. For example, the sport utility vehicle 404 may abort the lane change, both vehicles 402 and 404 may abort the lane change, etc. As such, the “alternate phase” may be used by the query engine 104 to find any number of alternate scenarios that satisfy the requirements of the query 400.

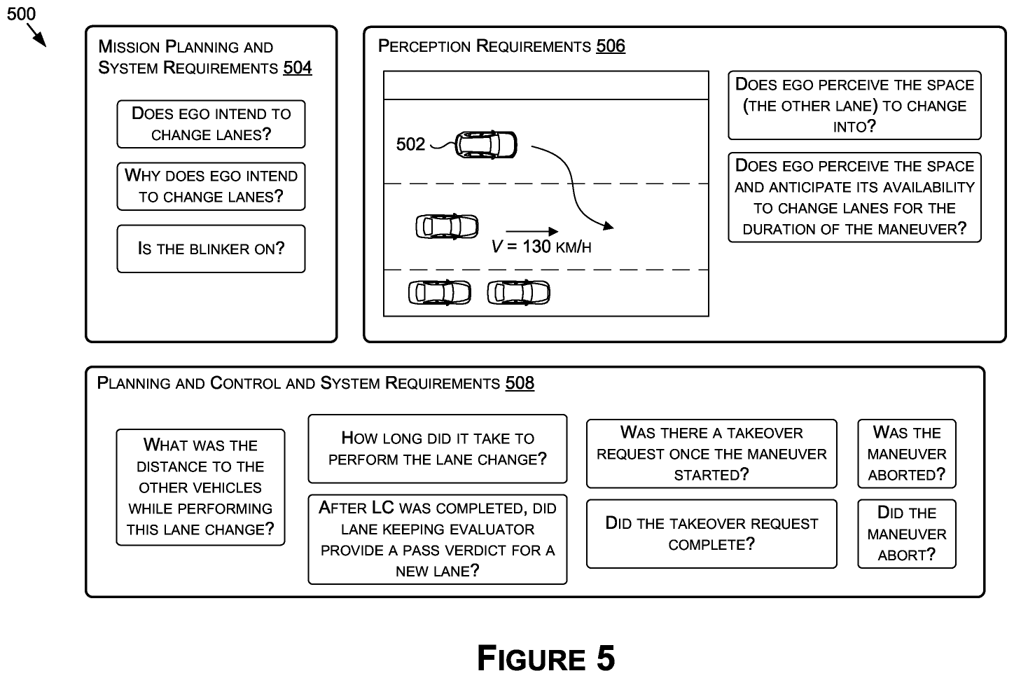

With reference to FIG. 5, FIG. 5 includes a visualization 500 of various requirements of a vehicle 700 that one or more queries may be generated to evaluate. The visualization 500 may correspond to an ego-vehicle 502 trying to change lanes to the right when there are various other vehicles on the roadway. The query generator 102 may be used to generate various queries to identify scenarios including lane changes, where these various mission planning and system requirements 504, perception requirements 506, and planning and control and system requirements 508 can be evaluated, tested, validated, and/or verified.

Referring again to FIG. 1, once a query has been generated using the query generator 102, the query (e.g., the high level declarative query, including domain specific elements) may be processed by the query engine 104 to generate an updated query (e.g., a lower level procedural query) for searching the data sources—e.g., ground truth simulation data 120, the ground truth real-world data 122, the map data 124, and/or the SUT data 126—to identify one or more scenarios represented in the data sources that satisfy the query. For example, as described herein, the declarative query from the query generator 102 may include implicit temporal and/or spatial relationships, and the query engine 104 may use the declarative query to generate an updated or procedural query including explicit temporal and/or spatial relationships.

The compiler 112 may generate the procedural query for searching the data sources using the search manager 114 and the cache manager 116. The compiler 112 may, for example, generate binary code using the declarative query from the query generator 102 to explicitly define the conditions of the desired scenarios to be identified in the data sources. The binary or machine code query may be executed by the query engine 104—e.g., the search manager 114 and/or the cache manager 116—to search the data sources for the scenario(s). The compiler 112 may analyze the declarative query from the query generator 102 to perform one or more optimizations in order to allow for the code to be executed more quickly and efficiently, and to reduce search time for identifying the desired scenarios. For example, in contrast to conventional approaches that performed brute force searches through all of the data from the data sources, the compiler 112 may use the implicit temporal and/or spatial relationships defined in the declarative query to generate explicit variables that may be used to optimize the search process.

As an example, and with respect to FIGS. 2A-2C, the compiler 112 may determine explicit time intervals from the implied time intervals in the query 200. Visualization 214 of FIG. 2C includes the times, t1, t2, and t3, which were implied in the query 200 (e.g., using the “parallel_phase,” “sequential_phase,” and “eventually” expressions). For example, sequential_phase may imply that there are two or more time intervals that happen sequentially, and parallel_phase may imply that two or more events, actors, etc. take place in parallel within at least one of the time intervals. As such, the complier 112 may use the sequential_phase and the parallel_phase to convert these implicit temporal and spatial relationships into a logical formula that describes the variables explicitly, as indicated by FIG. 2C.

By creating explicit variables t1, t2, and t3, the procedural query may include the explicit actors, x and y, in addition to the time variables, for a total of five variables. As a result, the search space may include a Cartesian product of these five variables, so a five-dimensional space may be searched over the data sources. As a non-limiting example, a frame of data may be generated and represented in the data sources every 33 milliseconds (e.g., 30 frames per second). Where a thirty second time frame is captured in the data sources, there may be 900 frames of data, and the search is in a five-dimensional space, which creates a large search space. Traditional methods may require searching the brute force approach to analyzing all 900 frames in five-dimensions, but the compiler 112 may be used to perform optimizations to reduce the search space. For example, the compiler 112 may analyze the declarative query expression to promote one or more sub-expressions to the “select” portion of the query. As a result, the query engine 104 may explicitly define sub-expressions to remove or prune portions of the search space that logically cannot include a match for the query expression. With reference to the query 200, between times t1 and t2 the ego-vehicle 202 is following vehicle x 204. This means that during the entire interval of time between t1 and t2 the ego-vehicle 202 should be following vehicle x 204—e.g., both vehicles 202 and 204 should be in the same lane 208. As such, the compiler 112 may define t1 and t2, determine if both the ego-vehicle 202 and vehicle x 204 are in the same lane at time t1 and t2 and, if not, update values of t1 and t2, or update the search space for finding t1 and t2 by explicitly defining periods of time where the relationship is satisfied. Because the search for the relationship at the beginning time and the end time of the interval includes analyzing two frames of data, this optimization may reduce the search space so as to increase the speed of the search. As another example, after selecting t1 and t2, the compiler 112 may analyze every x number of frames (e.g., every ten, twenty, fifty frames, etc.) between t1 and t2 to confirm the spatial relationship (e.g., both ego-vehicle 202 and vehicle x 204 are in the same lane 208), and where not satisfied at any frame, the times t1 and t2 may be updated at least such that t1 is after the known frame where the relationship was not satisfied. This type of optimization may reduce the search space such that more efficient searching of the data sources is executed while pruning out portions of the data where a match is known not to exist.

In some embodiments, additional sub-expressions may be added to the query that limit a search space based on distance or location. For example, for a query term such as “ego.is_following,” the compiler 112 may infer that the search space is only the driving surface (e.g., the compiler 112 may use ground truth data or map data indicating the driving surface coordinates, or more specifically the driving surface coordinates corresponding to the same lane as the ego-vehicle 202) and/or include a radius cap such that only vehicles that are on the driving surface of the ego-vehicle, in the same lane as the ego-vehicle, and/or within a specific radius or distance from the ego-vehicle 202 may be identified from the procedural query. To do this, the compiler 112 may add additional expressions to the query such as to “select x from vehicles where (ego.distance_to(x) is <30 m) and (x.is_in_ego_lane( )).” As a result, the implicit information and/or various optimization strategies (e.g., defining distances when terms such as “following” are used) may be used by the compiler 112 to generate more explicit searches that limit the search space and allow for filtering out of information from the data sources that is guaranteed not be a match.

In some embodiments, the compiler 112 may learn or determine that certain expressions in the query may more quickly filter out portions of the search space, or may be more challenging to satisfy. As such, the compiler 112 may rearrange one or more expressions to include the more restrictive or difficult to satisfy expressions before expressions that are easier to satisfy. For example, with respect to the query 300 of FIG. 3A, the compiler 112 may determine that is more challenging to find a scenario in the data sources that includes an identified stop line than it is to find a road with stops in maps. As such, the “stop_line” expression may be moved above the “road_with_stop” expression in the procedural query such that one or more of the scenarios that would satisfy “road_with_stop” are filtered out by the “stop_line” expression being executed first.

The procedural query generated by the compiler 112—after the one or more optimizations, in examples—may be used by the search manager 114 to execute the query to search the data sources for matching scenarios. For example, the search manager 114 may execute the search using pattern instantiation, unification or matching, and/or another type of search strategy. The search manager 114 may employ one or more optimizations to decrease runtime of the search. For example, with respect to FIGS. 2A-2C, the search manager may use the values of t1 and t2 to check whether vehicle x 204 and ego-vehicle 202 are in the same lane throughout the interval. Once the condition is found to not be true, the search manager 114 may skip forward to a new time, t1, where the condition is known to be satisfied. As a result, the search manager 114 may not increment by one frame at a time, but rather may jump forward in time once certain conditions are not found to be a match throughout the interval. Space optimizations may also be used by the search manager 114. For example, the search manager 114 may identify frames where one or more vehicles are in the ego-lane (and within a threshold distance) and discard frames where this requirement is not true. Similar to the time optimizations, the search manager 114 may then jump forward—instead of advancing frame by frame—to a frame where another vehicle is in the ego-lane. The rearrangement of expressions by the compiler 112 may result in search optimization as well, as the search manager 114 may execute the expressions in order. In some embodiments, the search manager 114 may perform this optimization in addition to or alternatively from the compiler 112. In either example, the search may be optimized using this short circuiting approach (e.g., profile guided optimization) to look at the data sources and identify the expressions that are more likely to fail, and then to reorder the query to create efficiency.

During execution of the search by the search manager 114, the cache manager 116 may cache data to optimize the search such that relevant information from the search may be cached for quick lookup. As such, in contrast to conventional database approaches that generate databases listing each variable from each frame of each data source, the query engine 104 may use the cache manager 116 to generate databases in cache memory as the search is being executed. As a result, the amount of information that is stored in the databases is only based on the data accessed as a result of an actual query—e.g., resulting in less compute to generate databases that are useful for the query at hand. This lazy computation—e.g., where compute is done on demand—thus results in less wasted information that would not match the query. The cache(s) used may be a flat cache, in examples, and/or a persistent cache.

As an example of caching, and with respect to the query 200 of FIGS. 2A-2C, when searching through the data sources at the times t1 and t2 for the vehicle x 204 and the vehicle y 206, the location, distances, orientation, type, and/or other information of the state of the actors, traffic lights, road conditions, etc. may be queried at one or more frames between t1 and t2, and this information, once extracted, may be stored in a database in the cache such that when evaluating over another time period that includes the same one or more frames, the information is already available. As such, if t1 and/or t2 are shifted forward in time due to an expression not being satisfied, the frames already queried in the prior search may have cached information that may be used to expedite the search. As a result, the compute requirements are saved on the front-end as large databases are not required to be computed to characterize all the data, and also at the back-end as the databases generated during search and stored in the cache may be used to expedite the search process.

The search manager 114 may access the data sources via associated providers 118. For example, the search manager 114 may access the ground truth simulation data 120 using the ground truth (GT) provider 118A, the ground truth real-world data 122 using the GT provider 118B, the map data 124 using map provider 118C, and/or SUT data 126 using the SUT provider 118D. The providers 118 may include application programming interfaces (APIs), in embodiments, or may include any components, features, and/or functionality for querying the data sources to identify various types of information. The data sources included in FIG. 1 are for example purposes only, and relate to an autonomous vehicle domain. However, as described herein, the data sources may be domain specific and may differ depending on the specific domain the system 100 is being implemented for. The data sources may generally include sequences of frames that each include snapshots or samples of the world state at the moment in time corresponding to the frame. As such, one or more of the data sources may correspond to a same frame or point in time, and may include timestamps or other time indicators to determine a relationship in time. For example, where the SUT data 126 is being used to determine perception accuracy from a real-world drive of a vehicle 700, the ground truth real-world data 122 corresponding to a point in time may be used to determine the perception accuracy from the SUT data 126 at the same point in time. As such, the query engine 104 may identify a scenario from the ground truth real-world data 122 that includes, e.g., a stop sign, and the query engine 104 may identify the SUT data 126 indicative of the vehicle's perception of the stop sign.

The data sources may include unstructured data, in embodiments, such that the data stored therein is not structured for retrieval for a specific query. For example, the data sources may include information about each of the actors in the environment. The cache manager 116, during the search, may store values retrieved during the search as structured data corresponding to the query. For example, where the query is looking for vehicles in a particular lane, the cache manager 116 may associate variables with one or more vehicles represented in the data, and may store their corresponding lane locations of the one or more vehicles. As such, during a next search iteration, this structured data—e.g., stored in a database in cache memory—may be accessed more readily.

The ground truth simulation data 120 may include snapshots, pictures, samples and/or other data about the world state of the simulated or virtual world at each frame. For example, the data 120 may include information about where actors are located in the world, their speeds, accelerations, poses, etc., information about the state of traffic lights or signals, information about the location of traffic signs, stop lines, etc. The simulation data may be generated using a simulation application, such as an autonomous vehicle drive simulator (e.g., NVIDIA's DRIVESIM). A non-limiting example of a simulator and a simulator application is described in U.S. Non-Provisional application Ser. No. 16/366,875, filed on Mar. 27, 2019.

The ground truth real-world data 122 may include snapshots, pictures, samples and/or other data about the world state of the real-world at each frame. For example, the data 120 may include information about where actors are located in the world, their speeds, accelerations, poses, etc., information about the state of traffic lights or signals, information about the location of traffic signs, stop lines, etc. The world-state may be perceived by the vehicle 700, other vehicles, and/or other systems. In some embodiments, the SUT data 126 may be used to generate the ground truth real-world data 122, while in other embodiments other systems or sensors of the vehicle 700 and/or another vehicle may be used to generate the ground truth real-world data 122. For example, when determining the accuracy of a new or updated deep neural network (DNN) for perceiving stop signs, the ground truth real-world data 122 may include information about the location of the stop sign from a DNN that is known to be accurate, and the SUT data 126 may include the outputs from the new or updated DNN. The outputs of the new or updated DNN may be compared against the ground truth real-world data (and/or map data 124 including information about a location or presence of a stop sign) to determine the accuracy of the new or updated DNN at perceiving stop signs. As another example, a high(er) resolution sensor may be used to generate the ground truth real-world data 122 and the SUT data 126 may include data from lower resolution sensors being tested for accuracy in deployment.

The map data 124 may include information about lane locations, poses, elevations, lane types, lane marking types, etc., and/or information about intersections, wait conditions, and/or other information. The map data 124 may be generated from a high definition (HD) map, a GPS-type map, and/or another type of map. The map data 124 may be used in combination with the ground truth simulation data 120 and/or the ground truth real-world data 122 to identify locations, lanes of travel, and/or other information about actors in the environment—including the ego-vehicle. For example, when determining what lane the ego-vehicle is located in, perception information of the vehicle as stored in the ground truth real-world data 122 in combination with map data 124 may be used to determine the lane that the ego-vehicle is in. This may be helpful in identifying the ego-lane and thus to identify other vehicles that are in the ego-lane, or in a lane adjacent the ego-lane.

The SUT data 126 may include a snapshot of how the autonomous vehicle software and/or sensors perceive the simulated or real-world. For example, the SUT data 126 may correspond to the outputs of an autonomous vehicle driving stack that includes various layers, such as a sensor layer, a perception layer, a world model management layer, a planning layer, a control layer, an actuation layer, an obstacle avoidance layer, and/or another type of layer(s). The SUT data 126 may be used in combination with the ground truth simulation data 120, the ground truth real-world data 122, and/or the map data 124 to determine how the vehicle 700 performs with respect to various requirements—such as but not limited to those described herein.

The scenarios and corresponding data from the data sources may be retrieved by the query engine 104 and used to evaluate or observe the performance of the vehicle 700, and/or to determine coverage information. For example, query expressions such as “assert,” “measure,” and/or “cover” may be executed on the identified scenarios to determine and/or report bugs, evaluate the performance in view of one or more key performance indicators (KPIs), populate performance reports, and/or annotate test plans or populate test bins to determine an amount of coverage from the available data in the data sources. Where coverage amounts are not satisfied—e.g., where a required test scenario is not present in the data, or enough alternatives of the test scenario are not present in the data—new drives in the real-world or in simulation may be conducted to attempt to satisfy the coverage requirements for the vehicle.

In some embodiments, performance of the vehicle 700 in simulation and in the real-world may be compared to improve the simulation system. For example, a same scenario may be tested in simulation and in the real-world using a real-world vehicle and a simulated version of the real-world vehicle (which may include hardware-in-the-loop, software-in-the-loop, etc.). These scenarios may be identified using the query engine 104, and the performance across both the real-world and the simulated versions may be compared. For example, a virtual sensor model may be used for the vehicle in the simulation environment that is intended to mimic the sensor model of the real-world sensor of the vehicle 700. However, when comparing the scenarios in real-world and simulation, it may be determined that the virtual sensor model is not as accurate as needed, and the virtual sensor model may be updated. This may result in a more accurate simulation test environment and a more accurate virtual representation of the vehicle.

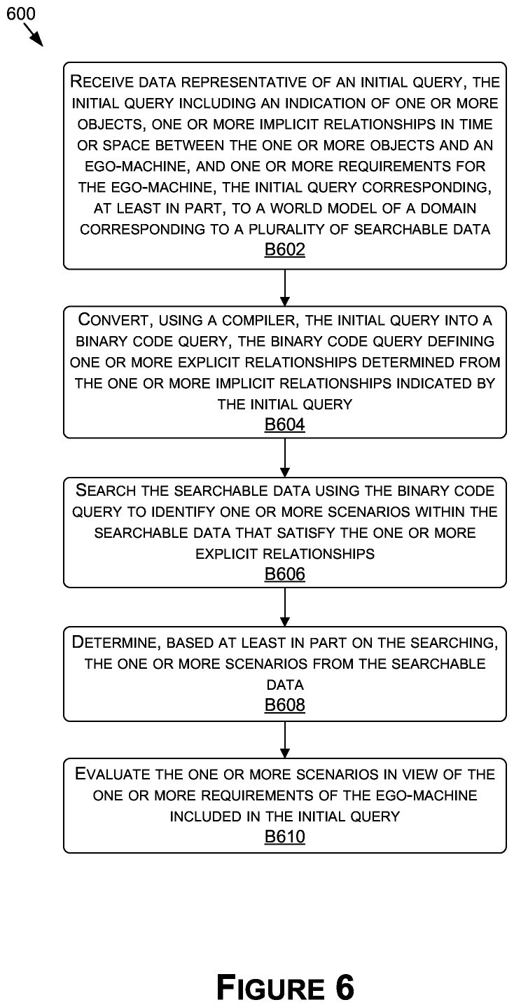

Now referring to FIG. 6, each block of method 600, described herein, comprises a computing process that may be performed using any combination of hardware, firmware, and/or software. For instance, various functions may be carried out by a processor executing instructions stored in memory. The method 600 may also be embodied as computer-usable instructions stored on computer storage media. The method 600 may be provided by a standalone application, a service or hosted service (standalone or in combination with another hosted service), or a plug-in to another product, to name a few. In addition, method 600 is described, by way of example, with respect to the system 100 of FIG. 1. However, this method 600 may additionally or alternatively be executed by any one system, or any combination of systems, including, but not limited to, those described herein.

FIG. 6 is a flow diagram of a method 600 for executing a query using a query engine, in accordance with some embodiments of the present disclosure The method 600, at block B602, includes receiving data representative of an initial query, the initial query including an indication of one or more objects, one or more implicit relationships in time or space between the one or more objects and an ego-machine, and one or more requirements for the ego-machine, the initial query corresponding, at least in part, to a world model of a domain corresponding to a plurality of searchable data. For example, the query engine 104 may receive an initial declarative query from the query generator 102.

The method 600, at block B604, includes converting, using a compiler, the initial query into a binary code query, the binary code query defining one or more explicit relationships determined from the one or more implicit relationships indicated by the initial query. For example, the compiler 112 may generate a procedural binary code query from the initial query that includes one or more explicit values or variables as determined from the implied expressions of the initial declarative query.

The method 600, at block B606, includes searching the searchable data using the binary code query to identify one or more scenarios within the searchable data that satisfy the one or more explicit relationships. For example, the search manager 114 and/or the cache manager 116 may be used to search the data sources using the binary code query.

The method 600, at block B608, includes determining, based at least in part on the searching, the one or more scenarios from the searchable data. For example, the query engine 104 may identify the one or more scenarios in the data sources.

The method 600, at block B610, includes evaluating the one or more scenarios in view of the one or more requirements of the ego-machine included in the initial query. For example, one or more evaluators, observers, and/or coverage collectors may be used to evaluate the ego-machine in view of the data from the one or more scenarios.

Example Autonomous Vehicle

FIG. 7A is an illustration of an example autonomous vehicle 700, in accordance with some embodiments of the present disclosure. The autonomous vehicle 700 (alternatively referred to herein as the “vehicle 700”) may include, without limitation, a passenger-carrying vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a drone, a vehicle coupled to a trailer, and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 700 may be capable of functionality in accordance with one or more of Level 3-Level 5 of the autonomous driving levels. For example, the vehicle 700 may be capable of conditional automation (Level 3), high automation (Level 4), and/or full automation (Level 5), depending on the embodiment.

The vehicle 700 may include components such as a chassis, a vehicle body, wheels (e.g., 2, 4, 6, 8, 18, etc.), tires, axles, and other components of a vehicle. The vehicle 700 may include a propulsion system 750, such as an internal combustion engine, hybrid electric power plant, an all-electric engine, and/or another propulsion system type. The propulsion system 750 may be connected to a drive train of the vehicle 700, which may include a transmission, to enable the propulsion of the vehicle 700. The propulsion system 750 may be controlled in response to receiving signals from the throttle/accelerator 752.

A steering system 754, which may include a steering wheel, may be used to steer the vehicle 700 (e.g., along a desired path or route) when the propulsion system 750 is operating (e.g., when the vehicle is in motion). The steering system 754 may receive signals from a steering actuator 756. The steering wheel may be optional for full automation (Level 5) functionality.

The brake sensor system 746 may be used to operate the vehicle brakes in response to receiving signals from the brake actuators 748 and/or brake sensors.

Controller(s) 736, which may include one or more system on chips (SoCs) 704 (FIG. 7C) and/or GPU(s), may provide signals (e.g., representative of commands) to one or more components and/or systems of the vehicle 700. For example, the controller(s) may send signals to operate the vehicle brakes via one or more brake actuators 748, to operate the steering system 754 via one or more steering actuators 756, to operate the propulsion system 750 via one or more throttle/accelerators 752. The controller(s) 736 may include one or more onboard (e.g., integrated) computing devices (e.g., supercomputers) that process sensor signals, and output operation commands (e.g., signals representing commands) to enable autonomous driving and/or to assist a human driver in driving the vehicle 700. The controller(s) 736 may include a first controller 736 for autonomous driving functions, a second controller 736 for functional safety functions, a third controller 736 for artificial intelligence functionality (e.g., computer vision), a fourth controller 736 for infotainment functionality, a fifth controller 736 for redundancy in emergency conditions, and/or other controllers. In some examples, a single controller 736 may handle two or more of the above functionalities, two or more controllers 736 may handle a single functionality, and/or any combination thereof.

The controller(s) 736 may provide the signals for controlling one or more components and/or systems of the vehicle 700 in response to sensor data received from one or more sensors (e.g., sensor inputs). The sensor data may be received from, for example and without limitation, global navigation satellite systems sensor(s) 758 (e.g., Global Positioning System sensor(s)), RADAR sensor(s) 760, ultrasonic sensor(s) 762, LIDAR sensor(s) 764, inertial measurement unit (IMU) sensor(s) 766 (e.g., accelerometer(s), gyroscope(s), magnetic compass(es), magnetometer(s), etc.), microphone(s) 796, stereo camera(s) 768, wide-view camera(s) 770 (e.g., fisheye cameras), infrared camera(s) 772, surround camera(s) 774 (e.g., 360 degree cameras), long-range and/or mid-range camera(s) 798, speed sensor(s) 744 (e.g., for measuring the speed of the vehicle 700), vibration sensor(s) 742, steering sensor(s) 740, brake sensor(s) (e.g., as part of the brake sensor system 746), and/or other sensor types.

One or more of the controller(s) 736 may receive inputs (e.g., represented by input data) from an instrument cluster 732 of the vehicle 700 and provide outputs (e.g., represented by output data, display data, etc.) via a human-machine interface (HMI) display 734, an audible annunciator, a loudspeaker, and/or via other components of the vehicle 700. The outputs may include information such as vehicle velocity, speed, time, map data (e.g., the HD map 722 of FIG. 7C), location data (e.g., the vehicle's 700 location, such as on a map), direction, location of other vehicles (e.g., an occupancy grid), information about objects and status of objects as perceived by the controller(s) 736, etc. For example, the HMI display 734 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 700 further includes a network interface 724 which may use one or more wireless antenna(s) 726 and/or modem(s) to communicate over one or more networks. For example, the network interface 724 may be capable of communication over LTE, WCDMA, UMTS, GSM, CDMA2000, etc. The wireless antenna(s) 726 may also enable communication between objects in the environment (e.g., vehicles, mobile devices, etc.), using local area network(s), such as Bluetooth, Bluetooth LE, Z-Wave, ZigBee, etc., and/or low power wide-area network(s) (LPWANs), such as LoRaWAN, SigFox, etc.

FIG. 7B is an example of camera locations and fields of view for the example autonomous vehicle 700 of FIG. 7A, in accordance with some embodiments of the present disclosure. The cameras and respective fields of view are one example embodiment and are not intended to be limiting. For example, additional and/or alternative cameras may be included and/or the cameras may be located at different locations on the vehicle 700.

The camera types for the cameras may include, but are not limited to, digital cameras that may be adapted for use with the components and/or systems of the vehicle 700. The camera(s) may operate at automotive safety integrity level (ASIL) B and/or at another ASIL. The camera types may be capable of any image capture rate, such as 60 frames per second (fps), 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom designed (3-D printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3-D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that include portions of the environment in front of the vehicle 700 (e.g., front-facing cameras) may be used for surround view, to help identify forward facing paths and obstacles, as well aid in, with the help of one or more controllers 736 and/or control SoCs, providing information critical to generating an occupancy grid and/or determining the preferred vehicle paths. Front-facing cameras may be used to perform many of the same ADAS functions as LIDAR, including emergency braking, pedestrian detection, and collision avoidance. Front-facing cameras may also be used for ADAS functions and systems including Lane Departure Warnings (LDW), Autonomous Cruise Control (ACC), and/or other functions such as traffic sign recognition.

A variety of cameras may be used in a front-facing configuration, including, for example, a monocular camera platform that includes a CMOS (complementary metal oxide semiconductor) color imager. Another example may be a wide-view camera(s) 770 that may be used to perceive objects coming into view from the periphery (e.g., pedestrians, crossing traffic or bicycles). Although only one wide-view camera is illustrated in FIG. 7B, there may any number of wide-view cameras 770 on the vehicle 700. In addition, long-range camera(s) 798 (e.g., a long-view stereo camera pair) may be used for depth-based object detection, especially for objects for which a neural network has not yet been trained. The long-range camera(s) 798 may also be used for object detection and classification, as well as basic object tracking.

One or more stereo cameras 768 may also be included in a front-facing configuration. The stereo camera(s) 768 may include an integrated control unit comprising a scalable processing unit, which may provide a programmable logic (FPGA) and a multi-core micro-processor with an integrated CAN or Ethernet interface on a single chip. Such a unit may be used to generate a 3-D map of the vehicle's environment, including a distance estimate for all the points in the image. An alternative stereo camera(s) 768 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 768 may be used in addition to, or alternatively from, those described herein.

Cameras with a field of view that include portions of the environment to the side of the vehicle 700 (e.g., side-view cameras) may be used for surround view, providing information used to create and update the occupancy grid, as well as to generate side impact collision warnings. For example, surround camera(s) 774 (e.g., four surround cameras 774 as illustrated in FIG. 7B) may be positioned to on the vehicle 700. The surround camera(s) 774 may include wide-view camera(s) 770, fisheye camera(s), 360 degree camera(s), and/or the like. Four example, four fisheye cameras may be positioned on the vehicle's front, rear, and sides. In an alternative arrangement, the vehicle may use three surround camera(s) 774 (e.g., left, right, and rear), and may leverage one or more other camera(s) (e.g., a forward-facing camera) as a fourth surround view camera.

Cameras with a field of view that include portions of the environment to the rear of the vehicle 700 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 798, stereo camera(s) 768), infrared camera(s) 772, etc.), as described herein.

FIG. 7C is a block diagram of an example system architecture for the example autonomous vehicle 700 of FIG. 7A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 700 in FIG. 7C are illustrated as being connected via bus 702. The bus 702 may include a Controller Area Network (CAN) data interface (alternatively referred to herein as a “CAN bus”). A CAN may be a network inside the vehicle 700 used to aid in control of various features and functionality of the vehicle 700, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 702 is described herein as being a CAN bus, this is not intended to be limiting. For example, in addition to, or alternatively from, the CAN bus, FlexRay and/or Ethernet may be used. Additionally, although a single line is used to represent the bus 702, this is not intended to be limiting. For example, there may be any number of busses 702, which may include one or more CAN busses, one or more FlexRay busses, one or more Ethernet busses, and/or one or more other types of busses using a different protocol. In some examples, two or more busses 702 may be used to perform different functions, and/or may be used for redundancy. For example, a first bus 702 may be used for collision avoidance functionality and a second bus 702 may be used for actuation control. In any example, each bus 702 may communicate with any of the components of the vehicle 700, and two or more busses 702 may communicate with the same components. In some examples, each SoC 704, each controller 736, and/or each computer within the vehicle may have access to the same input data (e.g., inputs from sensors of the vehicle 700), and may be connected to a common bus, such the CAN bus.

The vehicle 700 may include one or more controller(s) 736, such as those described herein with respect to FIG. 7A. The controller(s) 736 may be used for a variety of functions. The controller(s) 736 may be coupled to any of the various other components and systems of the vehicle 700, and may be used for control of the vehicle 700, artificial intelligence of the vehicle 700, infotainment for the vehicle 700, and/or the like.

The vehicle 700 may include a system(s) on a chip (SoC) 704. The SoC 704 may include CPU(s) 706, GPU(s) 708, processor(s) 710, cache(s) 712, accelerator(s) 714, data store(s) 716, and/or other components and features not illustrated. The SoC(s) 704 may be used to control the vehicle 700 in a variety of platforms and systems. For example, the SoC(s) 704 may be combined in a system (e.g., the system of the vehicle 700) with an HD map 722 which may obtain map refreshes and/or updates via a network interface 724 from one or more servers (e.g., server(s) 778 of FIG. 7D).

The CPU(s) 706 may include a CPU cluster or CPU complex (alternatively referred to herein as a “CCPLEX”). The CPU(s) 706 may include multiple cores and/or L2 caches. For example, in some embodiments, the CPU(s) 706 may include eight cores in a coherent multi-processor configuration. In some embodiments, the CPU(s) 706 may include four dual-core clusters where each cluster has a dedicated L2 cache (e.g., a 2 MB L2 cache). The CPU(s) 706 (e.g., the CCPLEX) may be configured to support simultaneous cluster operation enabling any combination of the clusters of the CPU(s) 706 to be active at any given time.

The CPU(s) 706 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 706 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 708 may include an integrated GPU (alternatively referred to herein as an “iGPU”). The GPU(s) 708 may be programmable and may be efficient for parallel workloads. The GPU(s) 708, in some examples, may use an enhanced tensor instruction set. The GPU(s) 708 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 708 may include at least eight streaming microprocessors. The GPU(s) 708 may use compute application programming interface(s) (API(s)). In addition, the GPU(s) 708 may use one or more parallel computing platforms and/or programming models (e.g., NVIDIA's CUDA).

The GPU(s) 708 may be power-optimized for best performance in automotive and embedded use cases. For example, the GPU(s) 708 may be fabricated on a Fin field-effect transistor (FinFET). However, this is not intended to be limiting and the GPU(s) 708 may be fabricated using other semiconductor manufacturing processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an L0 instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread scheduling capability to enable finer-grain synchronization and cooperation between parallel threads. The streaming microprocessors may include a combined L1 data cache and shared memory unit in order to improve performance while simplifying programming.

The GPU(s) 708 may include a high bandwidth memory (HBM) and/or a 16 GB HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 708 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 708 to access the CPU(s) 706 page tables directly. In such examples, when the GPU(s) 708 memory management unit (MMU) experiences a miss, an address translation request may be transmitted to the CPU(s) 706. In response, the CPU(s) 706 may look in its page tables for the virtual-to-physical mapping for the address and transmits the translation back to the GPU(s) 708. As such, unified memory technology may allow a single unified virtual address space for memory of both the CPU(s) 706 and the GPU(s) 708, thereby simplifying the GPU(s) 708 programming and porting of applications to the GPU(s) 708.

In addition, the GPU(s) 708 may include an access counter that may keep track of the frequency of access of the GPU(s) 708 to memory of other processors. The access counter may help ensure that memory pages are moved to the physical memory of the processor that is accessing the pages most frequently.

The SoC(s) 704 may include any number of cache(s) 712, including those described herein. For example, the cache(s) 712 may include an L3 cache that is available to both the CPU(s) 706 and the GPU(s) 708 (e.g., that is connected both the CPU(s) 706 and the GPU(s) 708). The cache(s) 712 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 704 may include an arithmetic logic unit(s) (ALU(s)) which may be leveraged in performing processing with respect to any of the variety of tasks or operations of the vehicle 700—such as processing DNNs. In addition, the SoC(s) 704 may include a floating point unit(s) (FPU(s))—or other math coprocessor or numeric coprocessor types—for performing mathematical operations within the system. For example, the SoC(s) 104 may include one or more FPUs integrated as execution units within a CPU(s) 706 and/or GPU(s) 708.

The SoC(s) 704 may include one or more accelerators 714 (e.g., hardware accelerators, software accelerators, or a combination thereof). For example, the SoC(s) 704 may include a hardware acceleration cluster that may include optimized hardware accelerators and/or large on-chip memory. The large on-chip memory (e.g., 4 MB of SRAM), may enable the hardware acceleration cluster to accelerate neural networks and other calculations. The hardware acceleration cluster may be used to complement the GPU(s) 708 and to off-load some of the tasks of the GPU(s) 708 (e.g., to free up more cycles of the GPU(s) 708 for performing other tasks). As an example, the accelerator(s) 714 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 714 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

The DLA(s) may perform any function of the GPU(s) 708, and by using an inference accelerator, for example, a designer may target either the DLA(s) or the GPU(s) 708 for any function. For example, the designer may focus processing of CNNs and floating point operations on the DLA(s) and leave other functions to the GPU(s) 708 and/or other accelerator(s) 714.

The accelerator(s) 714 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may enable components of the PVA(s) to access the system memory independently of the CPU(s) 706. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 714 (e.g., the hardware acceleration cluster) may include a computer vision network on-chip and SRAM, for providing a high-bandwidth, low latency SRAM for the accelerator(s) 714. In some examples, the on-chip memory may include at least 4 MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 704 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses. In some embodiments, one or more tree traversal units (TTUs) may be used for executing one or more ray-tracing related operations.

The accelerator(s) 714 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. In other words, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. According to process raw RADAR data (e.g., using a 4D Fast Fourier Transform) to provide Processed RADAR. In other examples, the PVA is used for time of flight depth processing, by processing raw time of flight data to provide processed time of flight data, for example.

The DLA may be used to run any type of network to enhance control and driving safety, including for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding box dimensions, ground plane estimate obtained (e.g. from another subsystem), inertial measurement unit (IMU) sensor 766 output that correlates with the vehicle 700 orientation, distance, 3D location estimates of the object obtained from the neural network and/or other sensors (e.g., LIDAR sensor(s) 764 or RADAR sensor(s) 760), among others.

The SoC(s) 704 may include data store(s) 716 (e.g., memory). The data store(s) 716 may be on-chip memory of the SoC(s) 704, which may store neural networks to be executed on the GPU and/or the DLA. In some examples, the data store(s) 716 may be large enough in capacity to store multiple instances of neural networks for redundancy and safety. The data store(s) 712 may comprise L2 or L3 cache(s) 712. Reference to the data store(s) 716 may include reference to the memory associated with the PVA, DLA, and/or other accelerator(s) 714, as described herein.

The SoC(s) 704 may include one or more processor(s) 710 (e.g., embedded processors). The processor(s) 710 may include a boot and power management processor that may be a dedicated processor and subsystem to handle boot power and management functions and related security enforcement. The boot and power management processor may be a part of the SoC(s) 704 boot sequence and may provide runtime power management services. The boot power and management processor may provide clock and voltage programming, assistance in system low power state transitions, management of SoC(s) 704 thermals and temperature sensors, and/or management of the SoC(s) 704 power states. Each temperature sensor may be implemented as a ring-oscillator whose output frequency is proportional to temperature, and the SoC(s) 704 may use the ring-oscillators to detect temperatures of the CPU(s) 706, GPU(s) 708, and/or accelerator(s) 714. If temperatures are determined to exceed a threshold, the boot and power management processor may enter a temperature fault routine and put the SoC(s) 704 into a lower power state and/or put the vehicle 700 into a chauffeur to safe stop mode (e.g., bring the vehicle 700 to a safe stop).

The processor(s) 710 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 710 may further include an always on processor engine that may provide necessary hardware features to support low power sensor management and wake use cases. The always on processor engine may include a processor core, a tightly coupled RAM, supporting peripherals (e.g., timers and interrupt controllers), various I/O controller peripherals, and routing logic.

The processor(s) 710 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 710 may further include a real-time camera engine that may include a dedicated processor subsystem for handling real-time camera management.

The processor(s) 710 may further include a high-dynamic range signal processor that may include an image signal processor that is a hardware engine that is part of the camera processing pipeline.

The processor(s) 710 may include a video image compositor that may be a processing block (e.g., implemented on a microprocessor) that implements video post-processing functions needed by a video playback application to produce the final image for the player window. The video image compositor may perform lens distortion correction on wide-view camera(s) 770, surround camera(s) 774, and/or on in-cabin monitoring camera sensors. In-cabin monitoring camera sensor is preferably monitored by a neural network running on another instance of the Advanced SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 708 is not required to continuously render new surfaces. Even when the GPU(s) 708 is powered on and active doing 3D rendering, the video image compositor may be used to offload the GPU(s) 708 to improve performance and responsiveness.

The SoC(s) 704 may further include a mobile industry processor interface (MIPI) camera serial interface for receiving video and input from cameras, a high-speed interface, and/or a video input block that may be used for camera and related pixel input functions. The SoC(s) 704 may further include an input/output controller(s) that may be controlled by software and may be used for receiving I/O signals that are uncommitted to a specific role.

The SoC(s) 704 may further include a broad range of peripheral interfaces to enable communication with peripherals, audio codecs, power management, and/or other devices. The SoC(s) 704 may be used to process data from cameras (e.g., connected over Gigabit Multimedia Serial Link and Ethernet), sensors (e.g., LIDAR sensor(s) 764, RADAR sensor(s) 760, etc. that may be connected over Ethernet), data from bus 702 (e.g., speed of vehicle 700, steering wheel position, etc.), data from GNSS sensor(s) 758 (e.g., connected over Ethernet or CAN bus). The SoC(s) 704 may further include dedicated high-performance mass storage controllers that may include their own DMA engines, and that may be used to free the CPU(s) 706 from routine data management tasks.

The SoC(s) 704 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 704 may be faster, more reliable, and even more energy-efficient and space-efficient than conventional systems. For example, the accelerator(s) 714, when combined with the CPU(s) 706, the GPU(s) 708, and the data store(s) 716, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks to be performed simultaneously and/or sequentially, and for the results to be combined together to enable Level 3-5 autonomous driving functionality. For example, a CNN executing on the DLA or dGPU (e.g., the GPU(s) 720) may include a text and word recognition, allowing the supercomputer to read and understand traffic signs, including signs for which the neural network has not been specifically trained. The DLA may further include a neural network that is able to identify, interpret, and provides semantic understanding of the sign, and to pass that semantic understanding to the path planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 708.

In some examples, a CNN for facial recognition and vehicle owner identification may use data from camera sensors to identify the presence of an authorized driver and/or owner of the vehicle 700. The always on sensor processing engine may be used to unlock the vehicle when the owner approaches the driver door and turn on the lights, and, in security mode, to disable the vehicle when the owner leaves the vehicle. In this way, the SoC(s) 704 provide for security against theft and/or carjacking.

In another example, a CNN for emergency vehicle detection and identification may use data from microphones 796 to detect and identify emergency vehicle sirens. In contrast to conventional systems, that use general classifiers to detect sirens and manually extract features, the SoC(s) 704 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 758. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 762, until the emergency vehicle(s) passes.

The vehicle may include a CPU(s) 718 (e.g., discrete CPU(s), or dCPU(s)), that may be coupled to the SoC(s) 704 via a high-speed interconnect (e.g., PCIe). The CPU(s) 718 may include an X86 processor, for example. The CPU(s) 718 may be used to perform any of a variety of functions, including arbitrating potentially inconsistent results between ADAS sensors and the SoC(s) 704, and/or monitoring the status and health of the controller(s) 736 and/or infotainment SoC 730, for example.

The vehicle 700 may include a GPU(s) 720 (e.g., discrete GPU(s), or dGPU(s)), that may be coupled to the SoC(s) 704 via a high-speed interconnect (e.g., NVIDIA's NVLINK). The GPU(s) 720 may provide additional artificial intelligence functionality, such as by executing redundant and/or different neural networks, and may be used to train and/or update neural networks based on input (e.g., sensor data) from sensors of the vehicle 700.

The vehicle 700 may further include the network interface 724 which may include one or more wireless antennas 726 (e.g., one or more wireless antennas for different communication protocols, such as a cellular antenna, a Bluetooth antenna, etc.). The network interface 724 may be used to enable wireless connectivity over the Internet with the cloud (e.g., with the server(s) 778 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 700 information about vehicles in proximity to the vehicle 700 (e.g., vehicles in front of, on the side of, and/or behind the vehicle 700). This functionality may be part of a cooperative adaptive cruise control functionality of the vehicle 700.

The network interface 724 may include a SoC that provides modulation and demodulation functionality and enables the controller(s) 736 to communicate over wireless networks. The network interface 724 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 700 may further include data store(s) 728 which may include off-chip (e.g., off the SoC(s) 704) storage. The data store(s) 728 may include one or more storage elements including RAM, SRAM, DRAM, VRAM, Flash, hard disks, and/or other components and/or devices that may store at least one bit of data.

The vehicle 700 may further include GNSS sensor(s) 758. The GNSS sensor(s) 758 (e.g., GPS, assisted GPS sensors, differential GPS (DGPS) sensors, etc.), to assist in mapping, perception, occupancy grid generation, and/or path planning functions. Any number of GNSS sensor(s) 758 may be used, including, for example and without limitation, a GPS using a USB connector with an Ethernet to Serial (RS-232) bridge.

The vehicle 700 may further include RADAR sensor(s) 760. The RADAR sensor(s) 760 may be used by the vehicle 700 for long-range vehicle detection, even in darkness and/or severe weather conditions. RADAR functional safety levels may be ASIL B. The RADAR sensor(s) 760 may use the CAN and/or the bus 702 (e.g., to transmit data generated by the RADAR sensor(s) 760) for control and to access object tracking data, with access to Ethernet to access raw data in some examples. A wide variety of RADAR sensor types may be used. For example, and without limitation, the RADAR sensor(s) 760 may be suitable for front, rear, and side RADAR use. In some example, Pulse Doppler RADAR sensor(s) are used.

The RADAR sensor(s) 760 may include different configurations, such as long range with narrow field of view, short range with wide field of view, short range side coverage, etc. In some examples, long-range RADAR may be used for adaptive cruise control functionality. The long-range RADAR systems may provide a broad field of view realized by two or more independent scans, such as within a 250 m range. The RADAR sensor(s) 760 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the vehicle's 700 surroundings at higher speeds with minimal interference from traffic in adjacent lanes. The other two antennae may expand the field of view, making it possible to quickly detect vehicles entering or leaving the vehicle's 700 lane.

Mid-range RADAR systems may include, as an example, a range of up to 760 m (front) or 80 m (rear), and a field of view of up to 42 degrees (front) or 750 degrees (rear). Short-range RADAR systems may include, without limitation, RADAR sensors designed to be installed at both ends of the rear bumper. When installed at both ends of the rear bumper, such a RADAR sensor systems may create two beams that constantly monitor the blind spot in the rear and next to the vehicle.

Short-range RADAR systems may be used in an ADAS system for blind spot detection and/or lane change assist.

The vehicle 700 may further include ultrasonic sensor(s) 762. The ultrasonic sensor(s) 762, which may be positioned at the front, back, and/or the sides of the vehicle 700, may be used for park assist and/or to create and update an occupancy grid. A wide variety of ultrasonic sensor(s) 762 may be used, and different ultrasonic sensor(s) 762 may be used for different ranges of detection (e.g., 2.5 m, 4 m). The ultrasonic sensor(s) 762 may operate at functional safety levels of ASIL B.

The vehicle 700 may include LIDAR sensor(s) 764. The LIDAR sensor(s) 764 may be used for object and pedestrian detection, emergency braking, collision avoidance, and/or other functions. The LIDAR sensor(s) 764 may be functional safety level ASIL B. In some examples, the vehicle 700 may include multiple LIDAR sensors 764 (e.g., two, four, six, etc.) that may use Ethernet (e.g., to provide data to a Gigabit Ethernet switch).

In some examples, the LIDAR sensor(s) 764 may be capable of providing a list of objects and their distances for a 360-degree field of view. Commercially available LIDAR sensor(s) 764 may have an advertised range of approximately 700 m, with an accuracy of 2 cm-3 cm, and with support for a 700 Mbps Ethernet connection, for example. In some examples, one or more non-protruding LIDAR sensors 764 may be used. In such examples, the LIDAR sensor(s) 764 may be implemented as a small device that may be embedded into the front, rear, sides, and/or corners of the vehicle 700. The LIDAR sensor(s) 764, in such examples, may provide up to a 120-degree horizontal and 35-degree vertical field-of-view, with a 200 m range even for low-reflectivity objects. Front-mounted LIDAR sensor(s) 764 may be configured for a horizontal field of view between 45 degrees and 135 degrees.

In some examples, LIDAR technologies, such as 3D flash LIDAR, may also be used. 3D Flash LIDAR uses a flash of a laser as a transmission source, to illuminate vehicle surroundings up to approximately 200 m. A flash LIDAR unit includes a receptor, which records the laser pulse transit time and the reflected light on each pixel, which in turn corresponds to the range from the vehicle to the objects. Flash LIDAR may allow for highly accurate and distortion-free images of the surroundings to be generated with every laser flash. In some examples, four flash LIDAR sensors may be deployed, one at each side of the vehicle 700. Available 3D flash LIDAR systems include a solid-state 3D staring array LIDAR camera with no moving parts other than a fan (e.g., a non-scanning LIDAR device). The flash LIDAR device may use a 5 nanosecond class I (eye-safe) laser pulse per frame and may capture the reflected laser light in the form of 3D range point clouds and co-registered intensity data. By using flash LIDAR, and because flash LIDAR is a solid-state device with no moving parts, the LIDAR sensor(s) 764 may be less susceptible to motion blur, vibration, and/or shock.

The vehicle may further include IMU sensor(s) 766. The IMU sensor(s) 766 may be located at a center of the rear axle of the vehicle 700, in some examples. The IMU sensor(s) 766 may include, for example and without limitation, an accelerometer(s), a magnetometer(s), a gyroscope(s), a magnetic compass(es), and/or other sensor types. In some examples, such as in six-axis applications, the IMU sensor(s) 766 may include accelerometers and gyroscopes, while in nine-axis applications, the IMU sensor(s) 766 may include accelerometers, gyroscopes, and magnetometers.

In some embodiments, the IMU sensor(s) 766 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 766 may enable the vehicle 700 to estimate heading without requiring input from a magnetic sensor by directly observing and correlating the changes in velocity from GPS to the IMU sensor(s) 766. In some examples, the IMU sensor(s) 766 and the GNSS sensor(s) 758 may be combined in a single integrated unit.

The vehicle may include microphone(s) 796 placed in and/or around the vehicle 700. The microphone(s) 796 may be used for emergency vehicle detection and identification, among other things.

The vehicle may further include any number of camera types, including stereo camera(s) 768, wide-view camera(s) 770, infrared camera(s) 772, surround camera(s) 774, long-range and/or mid-range camera(s) 798, and/or other camera types. The cameras may be used to capture image data around an entire periphery of the vehicle 700. The types of cameras used depends on the embodiments and requirements for the vehicle 700, and any combination of camera types may be used to provide the necessary coverage around the vehicle 700. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 7A and FIG. 7B.

The vehicle 700 may further include vibration sensor(s) 742. The vibration sensor(s) 742 may measure vibrations of components of the vehicle, such as the axle(s). For example, changes in vibrations may indicate a change in road surfaces. In another example, when two or more vibration sensors 742 are used, the differences between the vibrations may be used to determine friction or slippage of the road surface (e.g., when the difference in vibration is between a power-driven axle and a freely rotating axle).

The vehicle 700 may include an ADAS system 738. The ADAS system 738 may include a SoC, in some examples. The ADAS system 738 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 760, LIDAR sensor(s) 764, and/or a camera(s). The ACC systems may include longitudinal ACC and/or lateral ACC. Longitudinal ACC monitors and controls the distance to the vehicle immediately ahead of the vehicle 700 and automatically adjust the vehicle speed to maintain a safe distance from vehicles ahead. Lateral ACC performs distance keeping, and advises the vehicle 700 to change lanes when necessary. Lateral ACC is related to other ADAS applications such as LCA and CWS.

CACC uses information from other vehicles that may be received via the network interface 724 and/or the wireless antenna(s) 726 from other vehicles via a wireless link, or indirectly, over a network connection (e.g., over the Internet). Direct links may be provided by a vehicle-to-vehicle (V2V) communication link, while indirect links may be infrastructure-to-vehicle (I2V) communication link. In general, the V2V communication concept provides information about the immediately preceding vehicles (e.g., vehicles immediately ahead of and in the same lane as the vehicle 700), while the I2V communication concept provides information about traffic further ahead. CACC systems may include either or both I2V and V2V information sources. Given the information of the vehicles ahead of the vehicle 700, CACC may be more reliable and it has potential to improve traffic flow smoothness and reduce congestion on the road.

FCW systems are designed to alert the driver to a hazard, so that the driver may take corrective action. FCW systems use a front-facing camera and/or RADAR sensor(s) 760, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 760, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 700 crosses lane markings. A LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 700 if the vehicle 700 starts to exit the lane.

BSW systems detects and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 760, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 700 is backing up. Some RCTW systems include AEB to ensure that the vehicle brakes are applied to avoid a crash. RCTW systems may use one or more rear-facing RADAR sensor(s) 760, coupled to a dedicated processor, DSP, FPGA, and/or ASIC, that is electrically coupled to driver feedback, such as a display, speaker, and/or vibrating component.

Conventional ADAS systems may be prone to false positive results which may be annoying and distracting to a driver, but typically are not catastrophic, because the ADAS systems alert the driver and allow the driver to decide whether a safety condition truly exists and act accordingly. However, in an autonomous vehicle 700, the vehicle 700 itself must, in the case of conflicting results, decide whether to heed the result from a primary computer or a secondary computer (e.g., a first controller 736 or a second controller 736). For example, in some embodiments, the ADAS system 738 may be a backup and/or secondary computer for providing perception information to a backup computer rationality module. The backup computer rationality monitor may run a redundant diverse software on hardware components to detect faults in perception and dynamic driving tasks. Outputs from the ADAS system 738 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output may be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 704.

In other examples, ADAS system 738 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity makes the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware on primary computer is not causing material error.

In some examples, the output of the ADAS system 738 may be fed into the primary computer's perception block and/or the primary computer's dynamic driving task block. For example, if the ADAS system 738 indicates a forward crash warning due to an object immediately ahead, the perception block may use this information when identifying objects. In other examples, the secondary computer may have its own neural network which is trained and thus reduces the risk of false positives, as described herein.

The vehicle 700 may further include the infotainment SoC 730 (e.g., an in-vehicle infotainment system (IVI)). Although illustrated and described as a SoC, the infotainment system may not be a SoC, and may include two or more discrete components. The infotainment SoC 730 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the vehicle 700. For example, the infotainment SoC 730 may radios, disk players, navigation systems, video players, USB and Bluetooth connectivity, carputers, in-car entertainment, Wi-Fi, steering wheel audio controls, hands free voice control, a heads-up display (HUD), an HMI display 734, a telematics device, a control panel (e.g., for controlling and/or interacting with various components, features, and/or systems), and/or other components. The infotainment SoC 730 may further be used to provide information (e.g., visual and/or audible) to a user(s) of the vehicle, such as information from the ADAS system 738, autonomous driving information such as planned vehicle maneuvers, trajectories, surrounding environment information (e.g., intersection information, vehicle information, road information, etc.), and/or other information.

The infotainment SoC 730 may include GPU functionality. The infotainment SoC 730 may communicate over the bus 702 (e.g., CAN bus, Ethernet, etc.) with other devices, systems, and/or components of the vehicle 700. In some examples, the infotainment SoC 730 may be coupled to a supervisory MCU such that the GPU of the infotainment system may perform some self-driving functions in the event that the primary controller(s) 736 (e.g., the primary and/or backup computers of the vehicle 700) fail. In such an example, the infotainment SoC 730 may put the vehicle 700 into a chauffeur to safe stop mode, as described herein.

The vehicle 700 may further include an instrument cluster 732 (e.g., a digital dash, an electronic instrument cluster, a digital instrument panel, etc.). The instrument cluster 732 may include a controller and/or supercomputer (e.g., a discrete controller or supercomputer). The instrument cluster 732 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 730 and the instrument cluster 732. In other words, the instrument cluster 732 may be included as part of the infotainment SoC 730, or vice versa.

FIG. 7D is a system diagram for communication between cloud-based server(s) and the example autonomous vehicle 700 of FIG. 7A, in accordance with some embodiments of the present disclosure. The system 776 may include server(s) 778, network(s) 790, and vehicles, including the vehicle 700. The server(s) 778 may include a plurality of GPUs 784(A)-784(H) (collectively referred to herein as GPUs 784), PCIe switches 782(A)-782(H) (collectively referred to herein as PCIe switches 782), and/or CPUs 780(A)-780(B) (collectively referred to herein as CPUs 780). The GPUs 784, the CPUs 780, and the PCIe switches may be interconnected with high-speed interconnects such as, for example and without limitation, NVLink interfaces 788 developed by NVIDIA and/or PCIe connections 786. In some examples, the GPUs 784 are connected via NVLink and/or NVSwitch SoC and the GPUs 784 and the PCIe switches 782 are connected via PCIe interconnects. Although eight GPUs 784, two CPUs 780, and two PCIe switches are illustrated, this is not intended to be limiting. Depending on the embodiment, each of the server(s) 778 may include any number of GPUs 784, CPUs 780, and/or PCIe switches. For example, the server(s) 778 may each include eight, sixteen, thirty-two, and/or more GPUs 784.

The server(s) 778 may receive, over the network(s) 790 and from the vehicles, image data representative of images showing unexpected or changed road conditions, such as recently commenced road-work. The server(s) 778 may transmit, over the network(s) 790 and to the vehicles, neural networks 792, updated neural networks 792, and/or map information 794, including information regarding traffic and road conditions. The updates to the map information 794 may include updates for the HD map 722, such as information regarding construction sites, potholes, detours, flooding, and/or other obstructions. In some examples, the neural networks 792, the updated neural networks 792, and/or the map information 794 may have resulted from new training and/or experiences represented in data received from any number of vehicles in the environment, and/or based on training performed at a datacenter (e.g., using the server(s) 778 and/or other servers).

The server(s) 778 may be used to train machine learning models (e.g., neural networks) based on training data. The training data may be generated by the vehicles, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 790, and/or the machine learning models may be used by the server(s) 778 to remotely monitor the vehicles.

In some examples, the server(s) 778 may receive data from the vehicles and apply the data to up-to-date real-time neural networks for real-time intelligent inferencing. The server(s) 778 may include deep-learning supercomputers and/or dedicated AI computers powered by GPU(s) 784, such as a DGX and DGX Station machines developed by NVIDIA. However, in some examples, the server(s) 778 may include deep learning infrastructure that use only CPU-powered datacenters.

The deep-learning infrastructure of the server(s) 778 may be capable of fast, real-time inferencing, and may use that capability to evaluate and verify the health of the processors, software, and/or associated hardware in the vehicle 700. For example, the deep-learning infrastructure may receive periodic updates from the vehicle 700, such as a sequence of images and/or objects that the vehicle 700 has located in that sequence of images (e.g., via computer vision and/or other machine learning object classification techniques). The deep-learning infrastructure may run its own neural network to identify the objects and compare them with the objects identified by the vehicle 700 and, if the results do not match and the infrastructure concludes that the AI in the vehicle 700 is malfunctioning, the server(s) 778 may transmit a signal to the vehicle 700 instructing a fail-safe computer of the vehicle 700 to assume control, notify the passengers, and complete a safe parking maneuver.

For inferencing, the server(s) 778 may include the GPU(s) 784 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

Example Computing Device

FIG. 8 is a block diagram of an example computing device(s) 800 suitable for use in implementing some embodiments of the present disclosure. Computing device 800 may include an interconnect system 802 that directly or indirectly couples the following devices: memory 804, one or more central processing units (CPUs) 806, one or more graphics processing units (GPUs) 808, a communication interface 810, input/output (I/O) ports 812, input/output components 814, a power supply 816, one or more presentation components 818 (e.g., display(s)), and one or more logic units 820. In at least one embodiment, the computing device(s) 800 may comprise one or more virtual machines (VMs), and/or any of the components thereof may comprise virtual components (e.g., virtual hardware components). For non-limiting examples, one or more of the GPUs 808 may comprise one or more vGPUs, one or more of the CPUs 806 may comprise one or more vCPUs, and/or one or more of the logic units 820 may comprise one or more virtual logic units. As such, a computing device(s) 800 may include discrete components (e.g., a full GPU dedicated to the computing device 800), virtual components (e.g., a portion of a GPU dedicated to the computing device 800), or a combination thereof.

Although the various blocks of FIG. 8 are shown as connected via the interconnect system 802 with lines, this is not intended to be limiting and is for clarity only. For example, in some embodiments, a presentation component 818, such as a display device, may be considered an I/O component 814 (e.g., if the display is a touch screen). As another example, the CPUs 806 and/or GPUs 808 may include memory (e.g., the memory 804 may be representative of a storage device in addition to the memory of the GPUs 808, the CPUs 806, and/or other components). In other words, the computing device of FIG. 8 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 8.

The interconnect system 802 may represent one or more links or busses, such as an address bus, a data bus, a control bus, or a combination thereof. The interconnect system 802 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 806 may be directly connected to the memory 804. Further, the CPU 806 may be directly connected to the GPU 808. Where there is direct, or point-to-point connection between components, the interconnect system 802 may include a PCIe link to carry out the connection. In these examples, a PCI bus need not be included in the computing device 800.

The memory 804 may include any of a variety of computer-readable media. The computer-readable media may be any available media that may be accessed by the computing device 800. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 804 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 800. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 806 may be configured to execute at least some of the computer-readable instructions to control one or more components of the computing device 800 to perform one or more of the methods and/or processes described herein. The CPU(s) 806 may each include one or more cores (e.g., one, two, four, eight, twenty-eight, seventy-two, etc.) that are capable of handling a multitude of software threads simultaneously. The CPU(s) 806 may include any type of processor, and may include different types of processors depending on the type of computing device 800 implemented (e.g., processors with fewer cores for mobile devices and processors with more cores for servers). For example, depending on the type of computing device 800, the processor may be an Advanced RISC Machines (ARM) processor implemented using Reduced Instruction Set Computing (RISC) or an x86 processor implemented using Complex Instruction Set Computing (CISC). The computing device 800 may include one or more CPUs 806 in addition to one or more microprocessors or supplementary co-processors, such as math co-processors.

In addition to or alternatively from the CPU(s) 806, the GPU(s) 808 may be configured to execute at least some of the computer-readable instructions to control one or more components of the computing device 800 to perform one or more of the methods and/or processes described herein. One or more of the GPU(s) 808 may be an integrated GPU (e.g., with one or more of the CPU(s) 806 and/or one or more of the GPU(s) 808 may be a discrete GPU. In embodiments, one or more of the GPU(s) 808 may be a coprocessor of one or more of the CPU(s) 806. The GPU(s) 808 may be used by the computing device 800 to render graphics (e.g., 3D graphics) or perform general purpose computations. For example, the GPU(s) 808 may be used for General-Purpose computing on GPUs (GPGPU). The GPU(s) 808 may include hundreds or thousands of cores that are capable of handling hundreds or thousands of software threads simultaneously. The GPU(s) 808 may generate pixel data for output images in response to rendering commands (e.g., rendering commands from the CPU(s) 806 received via a host interface). The GPU(s) 808 may include graphics memory, such as display memory, for storing pixel data or any other suitable data, such as GPGPU data. The display memory may be included as part of the memory 804. The GPU(s) 808 may include two or more GPUs operating in parallel (e.g., via a link). The link may directly connect the GPUs (e.g., using NVLINK) or may connect the GPUs through a switch (e.g., using NVSwitch). When combined together, each GPU 808 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 806 and/or the GPU(s) 808, the logic unit(s) 820 may be configured to execute at least some of the computer-readable instructions to control one or more components of the computing device 800 to perform one or more of the methods and/or processes described herein. In embodiments, the CPU(s) 806, the GPU(s) 808, and/or the logic unit(s) 820 may discretely or jointly perform any combination of the methods, processes and/or portions thereof. One or more of the logic units 820 may be part of and/or integrated in one or more of the CPU(s) 806 and/or the GPU(s) 808 and/or one or more of the logic units 820 may be discrete components or otherwise external to the CPU(s) 806 and/or the GPU(s) 808. In embodiments, one or more of the logic units 820 may be a coprocessor of one or more of the CPU(s) 806 and/or one or more of the GPU(s) 808.

Examples of the logic unit(s) 820 include one or more processing cores and/or components thereof, such as Tensor Cores (TCs), Tensor Processing Units(TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 810 may include one or more receivers, transmitters, and/or transceivers that enable the computing device 800 to communicate with other computing devices via an electronic communication network, included wired and/or wireless communications. The communication interface 810 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet.

The I/O ports 812 may enable the computing device 800 to be logically coupled to other devices including the I/O components 814, the presentation component(s) 818, and/or other components, some of which may be built in to (e.g., integrated in) the computing device 800. Illustrative I/O components 814 include a microphone, mouse, keyboard, joystick, game pad, game controller, satellite dish, scanner, printer, wireless device, etc. The I/O components 814 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 800. The computing device 800 may be include depth cameras, such as stereoscopic camera systems, infrared camera systems, RGB camera systems, touchscreen technology, and combinations of these, for gesture detection and recognition. Additionally, the computing device 800 may include accelerometers or gyroscopes (e.g., as part of an inertia measurement unit (IMU)) that enable detection of motion. In some examples, the output of the accelerometers or gyroscopes may be used by the computing device 800 to render immersive augmented reality or virtual reality.

The power supply 816 may include a hard-wired power supply, a battery power supply, or a combination thereof. The power supply 816 may provide power to the computing device 800 to enable the components of the computing device 800 to operate.

The presentation component(s) 818 may include a display (e.g., a monitor, a touch screen, a television screen, a heads-up-display (HUD), other display types, or a combination thereof), speakers, and/or other presentation components. The presentation component(s) 818 may receive data from other components (e.g., the GPU(s) 808, the CPU(s) 806, etc.), and output the data (e.g., as an image, video, sound, etc.).

Example Data Center

FIG. 9 illustrates an example data center 900 that may be used in at least one embodiments of the present disclosure. The data center 900 may include a data center infrastructure layer 910, a framework layer 920, a software layer 930, and/or an application layer 940.

As shown in FIG. 9, the data center infrastructure layer 910 may include a resource orchestrator 912, grouped computing resources 914, and node computing resources (“node C.R.s”) 916(1)-916(N), where “N” represents any whole, positive integer. In at least one embodiment, node C.R.s 916(1)-916(N) may include, but are not limited to, any number of central processing units (“CPUs”) or other processors (including accelerators, field programmable gate arrays (FPGAs), graphics processors or graphics processing units (GPUs), etc.), memory devices (e.g., dynamic read-only memory), storage devices (e.g., solid state or disk drives), network input/output (“NW I/O”) devices, network switches, virtual machines (“VMs”), power modules, and/or cooling modules, etc. In some embodiments, one or more node C.R.s from among node C.R.s 916(1)-916(N) may correspond to a server having one or more of the above-mentioned computing resources. In addition, in some embodiments, the node C.R.s 916(1)-9161(N) may include one or more virtual components, such as vGPUs, vCPUs, and/or the like, and/or one or more of the node C.R.s 916(1)-916(N) may correspond to a virtual machine (VM).

In at least one embodiment, grouped computing resources 914 may include separate groupings of node C.R.s 916 housed within one or more racks (not shown), or many racks housed in data centers at various geographical locations (also not shown). Separate groupings of node C.R.s 916 within grouped computing resources 914 may include grouped compute, network, memory or storage resources that may be configured or allocated to support one or more workloads. In at least one embodiment, several node C.R.s 916 including CPUs, GPUs, and/or other processors may be grouped within one or more racks to provide compute resources to support one or more workloads. The one or more racks may also include any number of power modules, cooling modules, and/or network switches, in any combination.

The resource orchestrator 922 may configure or otherwise control one or more node C.R.s 916(1)-916(N) and/or grouped computing resources 914. In at least one embodiment, resource orchestrator 922 may include a software design infrastructure (“SDI”) management entity for the data center 900. The resource orchestrator 922 may include hardware, software, or some combination thereof.

In at least one embodiment, as shown in FIG. 9, framework layer 920 may include a job scheduler 932, a configuration manager 934, a resource manager 936, and/or a distributed file system 938. The framework layer 920 may include a framework to support software 932 of software layer 930 and/or one or more application(s) 942 of application layer 940. The software 932 or application(s) 942 may respectively include web-based service software or applications, such as those provided by Amazon Web Services, Google Cloud and Microsoft Azure. The framework layer 920 may be, but is not limited to, a type of free and open-source software web application framework such as Apache Spark™ (hereinafter “Spark”) that may utilize distributed file system 938 for large-scale data processing (e.g., “big data”). In at least one embodiment, job scheduler 932 may include a Spark driver to facilitate scheduling of workloads supported by various layers of data center 900. The configuration manager 934 may be capable of configuring different layers such as software layer 930 and framework layer 920 including Spark and distributed file system 938 for supporting large-scale data processing. The resource manager 936 may be capable of managing clustered or grouped computing resources mapped to or allocated for support of distributed file system 938 and job scheduler 932. In at least one embodiment, clustered or grouped computing resources may include grouped computing resource 914 at data center infrastructure layer 910. The resource manager 1036 may coordinate with resource orchestrator 912 to manage these mapped or allocated computing resources.

In at least one embodiment, software 932 included in software layer 930 may include software used by at least portions of node C.R.s 916(1)-916(N), grouped computing resources 914, and/or distributed file system 938 of framework layer 920. One or more types of software may include, but are not limited to, Internet web page search software, e-mail virus scan software, database software, and streaming video content software.

In at least one embodiment, application(s) 942 included in application layer 940 may include one or more types of applications used by at least portions of node C.R.s 916(1)-916(N), grouped computing resources 914, and/or distributed file system 938 of framework layer 920. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 934, resource manager 936, and resource orchestrator 912 may implement any number and type of self-modifying actions based on any amount and type of data acquired in any technically feasible fashion. Self-modifying actions may relieve a data center operator of data center 900 from making possibly bad configuration decisions and possibly avoiding underutilized and/or poor performing portions of a data center.

The data center 900 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 900. In at least one embodiment, trained or deployed machine learning models corresponding to one or more neural networks may be used to infer or predict information using resources described above with respect to the data center 900 by using weight parameters calculated through one or more training techniques, such as but not limited to those described herein.

In at least one embodiment, the data center 900 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 800 of FIG. 8—e.g., each device may include similar components, features, and/or functionality of the computing device(s) 800. In addition, where backend devices (e.g., servers, NAS, etc.) are implemented, the backend devices may be included as part of a data center 900, an example of which is described in more detail herein with respect to FIG. 9.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 800 described herein with respect to FIG. 8. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A system comprising:
one or more processing units; and
one or more memory units storing instructions that, when executed by the one or more processing units, cause the one or more processing units to execute operations comprising:
receiving data representative of an initial query, the initial query including an indication of one or more objects, one or more implicit relationships in time or space between the one or more objects and an ego-machine, and one or more requirements for the ego-machine, the initial query corresponding, at least in part, to a world model of a domain corresponding to a plurality of searchable data;
converting the initial query into a binary code query, the binary code query defining one or more explicit relationships determined from the one or more implicit relationships indicated by the initial query;
searching the searchable data using the binary code query to identify one or more scenarios within the searchable data that satisfy the one or more explicit relationships, the searchable data including one or more of simulation data, real-world data, map data, or system under test data;
determining, based at least in part on the searching, the one or more scenarios from the searchable data; and
observing the one or more scenarios based on the one or more requirements of the ego-machine included in the initial query.

2. The system of claim 1, wherein the domain includes one or more of an autonomous machine domain, an autonomous driving domain, a semi-autonomous driving domain, or a robotics domain.

3. The system of claim 1, wherein the observing the one or more scenarios in view of the one or more requirements includes evaluating one or more speed or acceleration conditions of the ego-machine during the one or more scenarios or one or more distance-based conditions during the one or more scenarios.

4. The system of claim 1, wherein the initial query corresponds to a high level scenario description language (HSDL) query.

5. The system of claim 1, further comprising one or more caches, wherein the searching includes performing multiple iterations of searching through the searchable data, and the operations further comprise:
during each iteration of the one or more iterations, storing values associated with the iteration in the one or more caches,
wherein subsequent iterations after the iteration include searching the values stored in the one or more caches.

6. The system of claim 1, wherein the initial query includes one or more query operators that are independent of the domain.

7. The system of claim 1, wherein the one or more requirements include an accuracy requirement for one or more perception tasks of the ego-machine, and wherein the observing the one or more scenarios in view of the one or more requirements includes:
determining perception data from the system under test data that corresponds in time to at least one of the simulation data, the real-world data, or the map data; and
testing the accuracy of the perception data using at least one of the simulation data, the real-world data, or the map data as ground truth data.

8. The system of claim 1, wherein the converting the initial query into the binary code query includes:
determining, using a compiler and based at least in part on one or more rules, an implicit relationship of the one or more implicit relationships that is more likely to fail; and
ordering, using the compiler, the binary code query such that the implicit relationship is searched for before another of the one or more implicit relationships that is less likely to fail.

9. The system of claim 1, wherein, once a condition associated with an explicit relationship of the one or more explicit relationships is determined to have failed during the searching, determining a subsequent time in the searchable data where the explicit relationship no longer fails, and restarting the searching at the subsequent time such that the searching does not include searching a subset of the data between the time when the condition failed and the subsequent time.

10. The system of claim 1, wherein the system is comprised in at least one of:
a control system for an autonomous or semi-autonomous machine;
a perception system for an autonomous or semi-autonomous machine;
a system for performing simulation operations;
a system for performing deep learning operations;
a system implemented using an edge device;
a system implemented using a robot;
a system incorporating one or more virtual machines (VMs);
a system implemented at least partially in a data center; or
a system implemented at least partially using cloud computing resources.

11. A processor comprising:
processing circuitry to:
receive data representative of a declarative language query, the declarative language query explicitly defining one or more actors, implicitly defining one or more relationships in time or space between the one or more objects and an ego-machine, and explicitly defining one or more requirements for the ego-machine;
convert the declarative language query into a procedural language query, the procedural language query explicitly defining the one or more relationships in time or space;
searching unstructured data using the procedural language query to identify one or more scenarios within the unstructured data that include the one or more actors and satisfy the one or more relationships, the unstructured data including one or more of simulation data, real-world data, map data, or system under test data;
determining, based at least in part on the searching, the one or more scenarios from the unstructured data; and
evaluating the one or more scenarios based on the one or more requirements of the ego-machine included in the declarative language query.

12. The processor of claim 11, wherein the declarative language query includes a first portion corresponding to a world model of a domain associated with the one or more actors and a second portion that is independent of the domain.

13. The processor of claim 11, wherein the one or more relationships are defined as alternatives such that the searching includes identifying at least a first scenario corresponding to a first alternative and a second scenario corresponding to a second alternative.

14. The processor of claim 11, wherein the converting includes updating a search ordering to an updated search ordering such that one or more conditions more likely to fail are ordered before one or more conditions less likely to fail.

15. The processor of claim 11, wherein, during the searching, a subset of the unstructured data is converted to structured data and stored in one or more caches such that at least a portion of the searching is using the structured data.

16. The processor of claim 11, wherein the unstructured data corresponds to the domain.

17. The processor of claim 11, wherein the processor is comprised in at least one of:
a control system for an autonomous or semi-autonomous machine;
a perception system for an autonomous or semi-autonomous machine;
a system for performing simulation operations;
a system for performing deep learning operations;
a system implemented using an edge device;
a system implemented using a robot;
a system incorporating one or more virtual machines (VMs);
a system implemented at least partially in a data center; or
a system implemented at least partially using cloud computing resources.

18. A method comprising:
receiving data representative of an initial query, the initial query including an indication of one or more objects, one or more implicit relationships in time or space between the one or more objects and an ego-machine, and one or more requirements for the ego-machine, the initial query corresponding, at least in part, to a world model of a domain corresponding to a plurality of searchable data;
converting the initial query into a binary code query, the binary code query defining one or more explicit relationships determined from the one or more implicit relationships indicated by the initial query;
searching the searchable data using the binary code query to identify one or more scenarios within the searchable data that satisfy the one or more explicit relationships, the searchable data including one or more of simulation data, real-world data, map data, or system under test data;
determining, based at least in part on the searching, the one or more scenarios from the searchable data; and
observing the one or more scenarios based on the one or more requirements of the ego-machine included in the initial query.

19. The method of claim 18, wherein the domain includes one or more of an autonomous machine domain, an autonomous driving domain, a semi-autonomous driving domain, or a robotics domain.

20. The method of claim 18, wherein the observing the one or more scenarios in view of the one or more requirements includes evaluating one or more speed or acceleration conditions of the ego-machine during the one or more scenarios or one or more distance-based conditions during the one or more scenarios.

21. The method of claim 18, wherein the searching includes performing multiple iterations of searching through the searchable data, and the operations further comprise:
during each iteration of the one or more iterations, generating one or more caches storing values associated with the iteration,
wherein subsequent iterations after the iteration include searching the values of the one or more caches.

22. The method of claim 18, wherein the one or more requirements include an accuracy requirement for one or more perception tasks of the ego-machine, and wherein the evaluating the one or more scenarios in view of the one or more requirements includes:
determining perception data from the system under test data that corresponds in time to at least one of the simulation data, the real-world data, or the map data; and
testing the accuracy of the perception data using at least one of the simulation data, the real-world data, or the map data as ground truth data.

23. The method of claim 18, wherein the converting the initial query into the binary code query includes:
determining, using a compiler and based at least in part on one or more rules, an implicit relationship of the one or more implicit relationships that is more likely to fail; and
ordering, using the compiler, the binary code query such that the implicit relationship is searched for before another of the one or more implicit relationships that is less likely to fail.

24. The method of claim 18, wherein, once a condition associated with an explicit relationship of the one or more explicit relationships is determined to have failed during the searching, determining a subsequent time in the searchable data where the explicit relationship no longer fails, and restarting the searching at the subsequent time such that the searching does not include searching a subset of the data between the time when the condition failed and the subsequent time.

25. The method of claim 18, wherein the searching includes at least one of pattern instantiation or unification in matching.

26. The method of claim 18, wherein the searching includes executing one or more of a short-circuit evaluation algorithm, a minimal evaluation algorithm, or a McCarthy evaluation algorithm.
